(19) United States
(12) Patent Application Publication
(10) Pub. No.: US 2026/0327378 A1
(43) Pub. Date: Oct. 22, 2026

(54) MATERIAL FOR FORMING INSULATING FILM, METHOD OF MANUFACTURING SEMICONDUCTOR DEVICE AND SEMICONDUCTOR DEVICE

(71) Applicant: HD MICROSYSTEMS, LTD., Shinjuku-ku, Tokyo (JP)

(72) Inventors: Kenya ADACHI, Parlin, NJ (US); Satoshi YONEDA, Shinjuku-ku, Tokyo (JP); Daisaku MATSUKAWA, Shinjuku-ku, Tokyo (JP)

(21) Appl. No.: 19/476,590

(22) PCT Filed: Apr. 19, 2024
(86) PCT No.: PCT/JP2024/015649

§ 371 Date: Oct. 17, 2025

(30) Foreign Application Priority Data
Apr. 19, 2023 (JP) 2023-068850

(51) Int. Cl. C08G 73/12; C08K 9/06; H10P 58/00; H10W 72/90; H10W 80/00; H10W 90/00; H10W 90/28

(52) U.S. Cl. CPC C08G 73/12; C08K 9/06; H10W 72/953; H10W 80/031; H10W 80/312; H10W 80/327; H10W 90/28; H10W 90/792; C08G 2330/00; C08K 2201/005; H10P 58/00

(57) ABSTRACT

A material for forming an insulating film contains (A) a polyimide precursor, (B) a solvent and (C) a filler, an i-line transmittance of an insulating film formed by the material for forming an insulating film is from 5% to 40% and the material has photosensitivity.

### TECHNICAL FIELD

The present invention relates to a material for forming an insulating film, a method of manufacturing a semiconductor device and a semiconductor device.

### BACKGROUND ART

In recent years, three-dimensional packaging of semiconductor chips has been considered in order to improve the integration density of an LSI (Large Scale Integrated Circuit). Non-Patent Document 1 discloses an example of three-dimensional packaging of semiconductor chips.

In the case of three-dimensional mounting of semiconductor chips by C2 W (Chip-to-Wafer) bonding, the use of hybrid bonding technology used for W2 W (Wafer-to-Wafer) bonding is studied in order to perform micro bonding of wiring between devices.

In C2 W hybrid bonding, there is a risk of misalignment caused by thermal expansion of a base material, a chip, or the like due to heating during bonding. To address such a problem, Patent Literature 1 discloses an example of a technique that can lower the bonding temperature by using a cyclic olefin resin.

### PRIOR ART DOCUMENT

### Patent Literature

[Patent Literature] JP 2019-204818 A

### Non-Patent Literature

[Non-Patent Literature 1] F. C. Chen et al., “System on Integrated Chips (SoIC TM) for 3D Heterogeneous Integration”, 2019 IEEE 69th Electronic Components and Technology Conference (ECTC), p. 594-599 (2019)

### SUMMARY OF INVENTION

However, in case in which an organic material such as a cyclic olefin resin, for example, benzocyclobutene is used for a material for an insulating film, heat resistance of the organic material is insufficient and therefore, when the insulating film is exposed to high temperatures during hybrid bonding, the organic material may be altered, which may result in poor bonding at the interface between a substrate and the insulating film.

The present inventors have been investigating the use of a polyimide precursor for a hybrid bonding material from the viewpoint of excellent heat resistance. However, when metal-metal such as copper-copper and insulating film-insulating film are bonding in the same process by hybrid bonding, there is a problem that poor metal-metal bonding (e.g., a gap at the bonding interface) is likely to occur.

The present inventors have focused on the fact that the difference in linear expansion coefficient (CTE) between an insulating film formed using a polyimide precursor and a metal causes poor metal-metal bonding, and have investigated a method of mixing a filler with a polyimide precursor to suppress poor metal-metal bonding. However, when a filler is used, the photosensitivity of a material for forming an insulating film tends to decrease. Therefore, a material for forming an insulating film that has photosensitivity and can reduce the linear expansion coefficient of the insulating film is desirable.

The disclosure has been made in light of the above, and the object is to provide a material for forming an insulating film that has photosensitivity and can reduce linear expansion coefficient of the insulating film, a method of manufacturing a semiconductor device using the material for forming an insulating film and a semiconductor device with an insulating film, which is formed by a material for forming an insulating film that has photosensitivity, and in which linear expansion coefficient is reduced.

### Solution to Problem

Specific means for achieving the above-mentioned objective include the following aspects.

<1> A material for forming an insulating film comprising:
(A) a polyimide precursor
(B) a solvent and
(C) a filler,
wherein an i-line transmittance of an insulating film formed by the material for forming an insulating film is from 5% to 40% and the material has photosensitivity.

<2> The material for forming an insulating film according to <1>, wherein the polyimide precursor includes a compound having a structural unit represented by the following general formula (1).

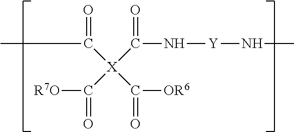

In general formula (1), X represents a tetravalent organic group, Y represents a divalent organic group, each of R⁶ and R⁷ independently represents a hydrogen atom or a monovalent organic group, and at least one of R⁶ and R⁷ has a polymerizable unsaturated bond.

<3> The material for forming an insulating film according to <1> or <2>, further comprising (D) a polymerizable monomer and (E) a photoinitiator.

<4> The material for forming an insulating film according to any one of <1> to <3>, wherein an average particle size of the filler is from 10 nm to 100 nm.

<5> The material for forming an insulating film according to any one of <1> to <4>, wherein the filler is surface-treated.

<6> The material for forming an insulating film according to any one of <1> to <5>, wherein the solvent includes a non-amide solvent.

<7> The material for forming an insulating film according to <6>, wherein the non-amide solvent includes a cyclic ester compound.

<8> The material for forming an insulating film according to any one of <1> to <7>, wherein the material is used to form an insulating film for a hybrid bonding.

<9> A method of manufacturing a semiconductor device comprising: producing an organic insulating film of at least one of a first organic insulating film or a second organic insulating film by using the material for forming an insulating film according to <8>, and bonding the first organic insulating film and the second organic insulating film.

<10> A method of manufacturing a semiconductor device comprising:
a process of forming a via by applying a material for forming an insulating film on a first substrate body and then removing a portion of the material for forming an insulating film applied on the first substrate body,
a process of preparing a first semiconductor substrate including a first organic insulating film and a first electrode provided on one side of the first substrate body, by curing the material for forming an insulating film in which the via is formed on the first substrate body to form the first organic insulating film and filing an electrode material into the via to form the first electrode,
a process of forming a via by applying a material for forming an insulating film on a second substrate body and then removing a portion of the material for forming an insulating film applied on the second substrate body,
a process of preparing a second semiconductor substrate including a second organic insulating film and a second electrode provided on one side of the second substrate body, by curing the material for forming an insulating film in which the via is formed on the second substrate body to form the second organic insulating film and filing an electrode material into the via to form the second electrode,
a process of obtaining a plurality of semiconductor chips by individuating the second semiconductor substrate, and
a process of attaching the first organic insulating film of the first semiconductor substrate to the second organic insulating film of the second insulating film each other and bonding the first electrode of the first semiconductor substrate and the second electrode of the semiconductor chip, wherein
at least one of the material for forming an insulating film applied on the first substrate body or the material for forming an insulating film applied on the second substrate body is the material for forming an insulating film according to <8>.

<11> A semiconductor device comprising:
a first semiconductor substrate including a first substrate body, and a first organic insulating film and a first electrode provided on one side of the first substrate body; and
a semiconductor chip including a semiconductor chip substrate body, and a second organic insulating film and a second electrode provided on one side of the semiconductor chip substrate body, wherein
the first organic insulating film of the first semiconductor substrate and the second organic insulating film of the semiconductor chip are bonded, and the first electrode of the first semiconductor substrate and the second electrode of the semiconductor chip are bonded, and
at least one of the first organic insulating film or the second organic insulating film is an insulating film obtained by curing a photosensitive material for forming an insulating film containing (A) a polyimide precursor, and (C) a filler, and an i-line transmittance of the insulating film is from 5% to 40%.

### Advantageous Effects of Invention

According to the disclosure, a material for forming an insulating film that has photosensitivity and can reduce linear expansion coefficient of the insulating film, a method of manufacturing a semiconductor device using the material for forming an insulating film and a semiconductor device with an insulating film, which is formed by a material for forming an insulating film that has photosensitivity, and in which linear expansion coefficient is reduced, can be provided.

### BRIEF DESCRIPTION OF DRAWINGS

FIG. 1 is a schematic sectional view of an example of a semiconductor device produced by a method of manufacturing a semiconductor device according to an embodiment of the invention.

FIG. 2 is a view illustrating a method of manufacturing the semiconductor device illustrated in FIG. 1, in sequence.

FIG. 3 is a view illustrating in more detail a bonding method in the method of manufacturing a semiconductor device illustrated in FIG. 2.

FIG. 4 illustrates, in sequence, processes after the process illustrated in FIG. 2 in the method for manufacturing the semiconductor device illustrated in FIG. 1.

FIG. 5 is a view illustrating an example of a method of manufacturing semiconductor devices according to one embodiment of the invention applied to a Chip-to-Wafer (C2 W).

### DESCRIPTION OF EMBODIMENTS

Hereinafter, embodiments for carrying out the disclosure will be described in detail. The disclosure, however, is not limited to the following embodiments.

In the disclosure, components (including elemental steps or the like) thereof are not necessary, unless specifically indicated otherwise. The same applies to numerical values and ranges thereof, which do not limit the disclosure.

In the disclosure, the term “process” includes not only a process that is independent of other processes, but also a process that is not clearly distinguishable from other processes, but whose purpose is achieved.

The numerical range indicated in the disclosure using “from A to B” includes A and B as the lower limit and the upper limit, respectively.

In a numerical range described in steps herein, an upper limit value or a lower limit value described in one numerical range may be replaced by upper limit values or lower limit values in other stepwise described numerical ranges. In a numerical range described herein, an upper limit value or a lower limit value of the numerical range may be replaced by values indicated in Examples.

In the disclosure, each component may contain a plurality of kinds of corresponding substances. When a composition contains a plurality of kinds of substances corresponding to each component, the content rate or content amount of each component means the total content rate or content amount of such plurality of substances present in the composition, unless otherwise specified.

The term “layer” or “film” herein encompasses, when observing an area in which the layer or film exists, cases in which the layer or film is formed over the entire area as well as cases in which the layer or film is formed only in a portion of the area.

In the disclosure, the thickness of a layer or film is a value given as the arithmetic mean of measured thicknesses at five points of a target layer or film.

The thickness of a layer or film can be measured using a micrometer or similar instrument. In the disclosure, when the thickness of a layer or film can be measured directly, a micrometer is used to measure the thickness. On the other hand, when the thickness of one layer or the total thickness of a plurality of layers is to be measured, the thickness may be measured by observing a section of an object to be measured using an electron microscope.

In the disclosure, the term “(meth)acrylic group” means “acrylic group” and “methacrylic group”, “(meth)acrylate” means “acrylate” and “methacrylate”, and “(meth)acryloyl” means “acryloyl” and “methacryloyl”.

In the disclosure, the concept of “insulating film” also encompasses an insulating layer.

In the disclosure, when a functional group has a substituent, the number of carbon atoms in the functional group means the total number of carbon atoms including the number of carbon atoms in the substituent.

When embodiments are described in the disclosure with reference to the drawings, the configuration of the embodiments is not limited to the configuration illustrated in the drawings. The sizes of the components in each drawing are conceptual, and the relative relationship of sizes between components is not limited thereto.

### <Material for Forming Insulating Film>

A material for forming an insulating film is a material containing (A) a polyimide precursor, (B) a solvent and (C) a filler, and an i-line transmittance of an insulating film formed by the material for forming an insulating film is from 5% to 40% and the material has photosensitivity.

The material for forming an insulating film has photosensitivity and can reduce linear expansion coefficient of the insulating film. The reason for this is not clear, but can be considered as follows.

When the i-line transmittance of the insulating film formed from the material for forming an insulating film of the disclosure is 5% or more, deterioration in photosensitivity can be suppressed, resulting in a material for forming an insulating film with high resolution.

Furthermore, when the material for forming an insulating film contains (C) a filler in addition to (A) a polyimide precursor and an insulating film is formed by the material, there is a tendency that the linear expansion coefficient of the insulating film is lower than that of an insulating film without (C) a filler. As a result, it is possible to reduce the difference in linear expansion coefficient between the insulating film and a metal such as copper. This makes it possible to suppress poor bonding between metals due to the difference in linear expansion coefficient between the insulating film and a metal such as copper.

In the material for forming an insulating film, the linear expansion coefficient of the insulating film after curing is preferably 60 ppm/K or less, more preferably 50 ppm/K or less, and still more preferably 45 ppm/K or less. Thereby, it is possible to suitably suppress bonding poor bonding between metals. The lower limit of the insulating film is not particularly limited, and for example, the linear expansion coefficient may be 20 ppm/K or more or may be 25 ppm/K or more.

The linear expansion coefficient indicates the rate per unit of temperature at which the length of the insulating film expands due to an increase in temperature and can be calculated by measuring the change in length of the insulating film from 50° C. to 100° C. using a thermomechanical analyzer, or the like.

The i-line transmittance of an insulating film formed by the material for forming an insulating film of the disclosure is from 5% to 40%, for example, may be from 10% to 40% or may be from 12% to 30%.

The i-line transmittance of an insulating film can be adjusted by, for example, a kind of (A) a polyimide precursor, a kind of (B) a solvent, a kind of (C) a filler or the like.

The method for measuring the i-line transmittance is as follows. Specifically, a material for forming an insulating film is applied to a glass substrate by spin coating or the like, and the coating is dried at 100° C. for 2 minutes, and then dried at 110° C. for 2 minutes to form a resin film. The i-line transmittance of the resin film is measured using a spectrophotometer (for example, a U-3900H spectrophotometer manufactured by Hitachi High-Tech Science Corporation). The obtained value is regarded as the i-line transmittance of the insulating film.

The material for forming an insulating film of the disclosure may be a material used to form an insulating film for a hybrid bonding. For example, the material for forming an insulating film of the disclosure may be a material that is applied to a technique such as W2 W (Wafer-to-Wafer) bonding, C2 W (Chip-to-Wafer) bonding, or the like. When insulating films are bonded together to perform a hybrid bonding, it is sufficient that at least one of the insulating films is formed from the material for forming an insulating film of the disclosure, and it is preferable that both insulating films are formed from the material for forming an insulating film of the disclosure.

### ((A) Polyimide Precursor)

The material for forming an insulating film contains (A) a polyimide precursor (hereinafter, also referred to as “(A) component”).

(A) the component is preferably at least one resin selected from the group consisting of a polyamic acid, a polyamic acid ester, a polyamic acid salt, and a polyamic acid amide. The polyamic acid ester and polyamic acid amide are compounds in which the hydrogen atoms of at least some of the carboxy groups in a polyamic acid are substituted with monovalent organic groups, and the polyamic acid salt is a compound in which at least some of the carboxy groups in a polyamic acid form a salt structure with a basic compound having a pH of greater than 7.

(A) the component may have a polymerizable unsaturated bond.

(A) the component preferably contains a compound containing a structural unit represented by the following Formula (1). As a result, a semiconductor device including an insulating film exhibiting high reliability tends to be obtained.

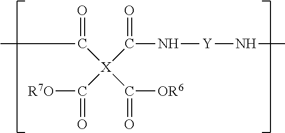

In Formula (1), X represents a tetravalent organic group, Y represents a divalent organic group, each of R⁶ and R⁷ independently represents a hydrogen atom or a monovalent organic group and at least one of R⁶ and R⁷ has a polymerizable unsaturated bond.

A polyimide precursor may contain a plurality of structural units represented by the above-described Formula (1), and X, Y, R⁶, and R⁷ in the plurality of structural units may be the same or different from each other.

The combination of R⁶ and R⁷ is not particularly limited as long as R⁶ and R⁷ are independently a hydrogen atom or a monovalent organic group, respectively. For example, one in R⁶ and R⁷ may be a hydrogen atom and the other in R⁶ and R⁷ may be a monovalent organic group as described below, or both may be the same or different monovalent organic groups. When a polyimide precursor contains a plurality of structural units represented by the above-described Formula (1) as described above, combinations of R⁶ and R⁷ of the structural units may be the same or different from each other.

In Formula (1), the number of carbon atoms of a tetravalent organic group represented by X is preferably from 4 to 25, more preferably from 5 to 13, and still more preferably from 6 to 12.

A tetravalent organic group represented by X may contain an aromatic ring. Examples of the aromatic ring include an aromatic hydrocarbon group (for example, the number of carbon atoms constituting the aromatic ring is from 6 to 20) and an aromatic heterocyclic group (for example, the number of atoms constituting the heterocyclic ring is from 5 to 20). The tetravalent organic group represented by X is preferably an aromatic hydrocarbon group. Examples of the aromatic hydrocarbon group include a benzene ring, a naphthalene ring, and a phenanthrene ring.

When a tetravalent organic group represented by X contains an aromatic ring, each aromatic ring may include a substituent or may be unsubstituted. Examples of a substituent of an aromatic ring include an alkyl group, a fluorine atom, an alkyl halide group, a hydroxyl group, and an amino group.

When a tetravalent organic group represented by X contains a benzene ring, the tetravalent organic group represented by X preferably contains from one to four benzene rings, more preferably contains from one to three benzene rings, and still more preferably contains one or two benzene rings.

When the tetravalent organic group represented by X contains two or more benzene rings, each benzene ring may be linked by a single bond or by a linking group such as an alkylene group, alkylene halide group, carbonyl group, sulfonyl group, an ether bond (—O—), a sulfide bond (—S—), a silylene bond (—Si(R^{A})₂— in which each of the two RAs independently represents a hydrogen atom, an alkyl group, or a phenyl group), or a siloxane bond (—O—(Si(R^{B})₂—O—)ₙ in which each of the two R^{B}s independently represents a hydrogen atom, an alkyl group or a phenyl group, and n is an integer of 1 or 2 or more), a conjugated linking group which is a combination of at least two of these linking groups, or the like. Two benzene rings may be joined in two positions by at least one of a single bond or a linking group to form a 5- or 6-membered ring containing a linking group between the two benzene rings.

In Formula (1), the —COOR⁶ group and the —CONH— group are preferably in the ortho position with each other, or the —COOR⁷ group and the —CO— group are preferably in the ortho position with each other.

Specific examples of the tetravalent organic group represented by X include groups represented by the following Formula (A) to Formula (F). Among these, from the viewpoint of obtaining an insulating film with excellent flexibility and more reduced generation of a void at a bonding interface, a group represented by the following Formula (E) is preferable, a group represented by the following Formula (E) in which C contains an ether bond is more preferable, and an ether bond is still more preferable. The following Formula (F) is a structure in which C in the following Formula (E) is a single bond.

The disclosure is not limited to the following specific examples.

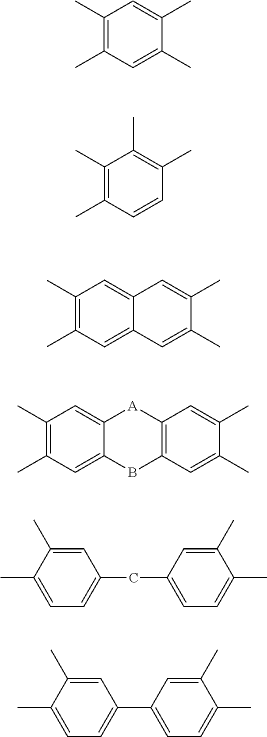

In Formula (D), each of A and B is independently a single bond or a divalent group not conjugated to a benzene ring. However, not both A and B are a single bond. Examples of the divalent group not conjugated to a benzene ring include a methylene group, a methylene halide group, a methyl methylene halide group, a carbonyl group, a sulfonyl group, an ether bond (—O—), a sulfide bond (—S—), and a silylene bond (—Si(R^{A})₂— in which each of the two RAs independently represents a hydrogen atom, an alkyl group, or a phenyl group). Among them, each of A and B is preferably independently a methylene group, a bis(trifluoromethyl)methylene group, a difluoromethylene group, an ether bond, a sulfide bond, or the like, and more preferably an ether bond.

In Formula (E), C represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂— in which each of the two RAs independently represents a hydrogen atom, an alkyl group, or a phenyl group), a siloxane bond (—O—(Si(R^{B})₂—O—)ₙ in which each of the two R^{B}s independently represents a hydrogen atom, an alkyl group or a phenyl group, and n is an integer of 1 or 2 or more), or a divalent group combining at least two of these. C preferably contains an ether bond and is preferably an ether bond.

C may contain a structure represented by the following Formula (C1).

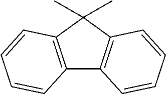

An alkylene group represented by C in Formula (E) is preferably an alkylene group having from 1 to 10 carbon atoms, more preferably an alkylene group having from 1 to 5 carbon atoms, and still more preferably an alkylene group having 1 or 2 carbon atoms.

Examples of an alkylene group represented by C in Formula (E) include: a linear alkylene group such as a methylene group, an ethylene group, a trimethylene group, a tetramethylene group, a pentamethylene group, or a hexamethylene group; and a branched chain alkylene group such as a methylmethylene group, a methylethylene group, an ethylmethylene group, a dimethylmethylene group, a 1,1-dimethylethylene group, a 1-methyltrimethylene group, a 2-methyltrimethylene group, an ethylethylene group, a 1-methyltetramethylene group, a 2-methyltetramethylene group, a 1-ethyltrimethylene group, a 2-ethyltrimethylene group, a 1,1-dimethyltrimethylene group, a 1,2-dimethyltrimethylene group, a 2,2-dimethyltrimethylene group, a 1-methylpentamethylene group, a 2-methylpentamethylene group, a 3-methylpentamethylene group, a 1-ethyltetramethylene group, a 2-ethyltetramethylene group, a 1,1-dimethyltetramethylene group, a 1,2-dimethyltetramethylene group, a 2,2-dimethyltetramethylene group, a 1,3-dimethyltetramethylene group, a 2,3-dimethyltetramethylene group, or a 1,4-dimethyltetramethylene group. Among these, a methylene group is preferable.

An alkylene halide group represented by C in Formula (E) is preferably an alkylene halide group having from 1 to 10 carbon atoms, more preferably an alkylene halide group having from 1 to 5 carbon atoms, and still more preferably an alkylene halide group having from 1 to 3 carbon atoms.

Specific examples of an alkylene halide group represented by C in Formula (E) include an alkylene group in which at least one hydrogen atom in the alkylene group represented by C in Formula (E) above is substituted with a halogen atom such as a fluorine atom or a chlorine atom. Among these, a fluoromethylene group, a difluoromethylene group, a hexafluorodimethylmethylene group, or the like is preferable.

An alkyl group represented by R^{A} or R^{B} contained in the above-described silylene bond or siloxane bond is preferably an alkyl group having from 1 to 5 carbon atoms, more preferably an alkyl group having from 1 to 3 carbon atoms, and still more preferably an alkyl group having from 1 to 2 carbon atoms. Specific examples of an alkyl group represented by R^{A} or R^{B} include a methyl group, an ethyl group, an n-propyl group, an isopropyl group, an n-butyl group, an isobutyl group, an s-butyl group, and a t-butyl group.

Specific examples of a tetravalent organic group represented by X may be a group represented by the following Formula (J) to Formula (O).

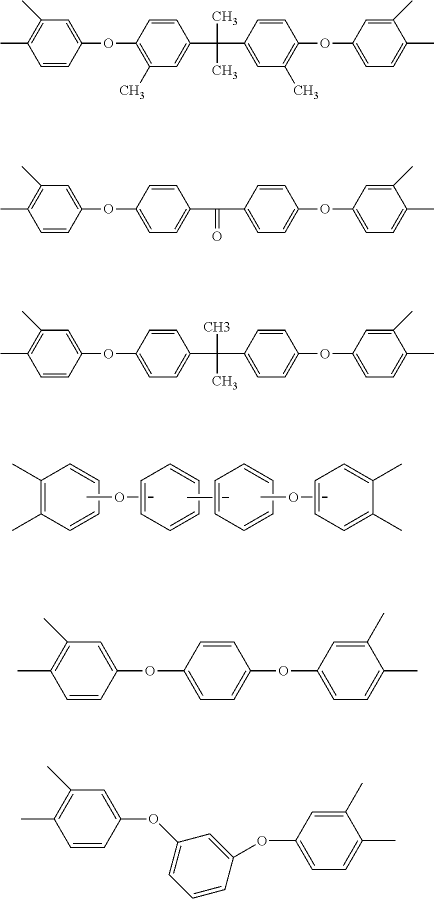

In Formula (1), the number of carbon atoms of a divalent organic group represented by Y is preferably from 4 to 25, more preferably from 6 to 20, and still more preferably from 12 to 18.

A skeleton of a divalent organic group represented by Y may be the same as a skeleton of a tetravalent organic group represented by X, and a preferable skeleton of a divalent organic group represented by Y may be the same as a preferable skeleton of a tetravalent organic group represented by X. The skeleton of a divalent organic group represented by Y may be a structure of a tetravalent organic group represented by X, which is substituted at two bonding positions with an atom (for example, a hydrogen atom) or a functional group (for example, an alkyl group).

A divalent organic group represented by Y may be a divalent aliphatic group or a divalent aromatic group. From the viewpoint of heat resistance, the divalent organic group represented by Y is preferably a divalent aromatic group. Examples of the divalent aromatic group include a divalent aromatic hydrocarbon group (for example, the number of carbon atoms constituting the aromatic ring is from 6 to 20), and a divalent aromatic heterocyclic group (for example, the number of atoms constituting the heterocyclic ring is from 5 to 20), and a divalent aromatic hydrocarbon group is preferable.

Specific examples of the divalent aromatic group represented by Y include groups represented by the following Formula (G) and Formula (H). Among these, from the viewpoint of obtaining an insulating film with excellent flexibility and more suppressed generation of a void at a bonding interface, a group represented by the following Formula (H) is preferable, a group represented by the following Formula (H) in which D is a single bond or a group containing an ether bond is more preferable, a group represented by the following Formula (H) in which D is a single bond or a group containing an ether bond is still more preferable, a group represented by the following Formula (H) in which D is a group containing an ether bond is particularly preferable, and a group represented by the following Formula (H) in which D is an ether bond is extremely preferable.

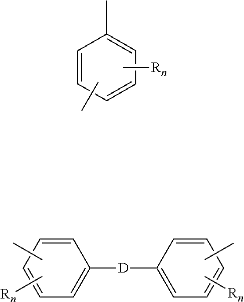

In Formula (G) to Formula (H), R independently represents an alkyl group, an alkoxy group, an alkyl halide group, a phenyl group, or a halogen atom, and n independently represents an integer from 0 to 4.

In Formula (H), D represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂— in which each of the two RAs independently represents a hydrogen atom, an alkyl group, or a phenyl group), a siloxane bond (—O—(Si(R^{B})₂—O—) n in which each of the two R^{B}s independently represents a hydrogen atom, an alkyl group or a phenyl group, and n is an integer of 1 or 2 or more), or a divalent group combining at least two of these. D may be a structure represented by the following Formula (C1). Specific examples of D in Formula (H) are the same as specific examples of C in Formula (E).

D in Formula (H) is preferably a single bond, an ether bond, a group containing an ether bond and a phenylene group, a group containing an ether bond, a phenylene group, and an alkylene group, or the like.

An alkyl group represented by R in Formula (G) to Formula (H) is preferably an alkyl group having from 1 to 10 carbon atoms, more preferably an alkyl group having from 1 to 5 carbon atoms, and still more preferably an alkyl group having 1 or 2 carbon atoms.

Specific examples of the alkyl group represented by R in Formula (G) to Formula (H) include a methyl group, an ethyl group, an n-propyl group, an isopropyl group, an n-butyl group, an isobutyl group, an s-butyl group, and a t-butyl group.

An alkoxy group represented by R in Formula (G) to Formula (H) is preferably an alkoxy group having from 1 to 10 carbon atoms, more preferably an alkoxy group having from 1 to 5 carbon atoms, and still more preferably an alkoxy group having from 1 or 2 carbon atoms.

Specific examples of an alkoxy group represented by R in Formula (G) to Formula (H) include a methoxy group, an ethoxy group, an n-propoxy group, an isopropoxy group, an n-butoxy group, an isobutoxy group, an s-butoxy group, and a t-butoxy group.

An alkyl halide group represented by R in Formula (G) to Formula (H) is preferably an alkyl halide group having from 1 to 5 carbon atoms, more preferably an alkyl halide group having from 1 to 3 carbon atoms, and still more preferably an alkyl halide group having from 1 or 2 carbon atoms.

Specific examples of an alkyl halide group represented by R in Formula (G) to Formula (H) include an alkyl group in which at least one hydrogen atom in the alkyl group represented by R in Formula (G) to Formula (H) is substituted with a halogen atom such as a fluorine atom or a chlorine atom. Among them, a fluoromethyl group, a difluoromethyl group, a trifluoromethyl group, or the like is preferable.

Each of n in Formula (G) to Formula (H) is independently preferably from 0 to 2, more preferably from 0 to 1, and still more preferably from 0.

Specific examples of a divalent aliphatic group represented by Y include a linear or branched chain alkylene group, a cycloalkylene group, and a divalent group having a polyalkylene oxide structure.

A linear or branched chain alkylene group represented by Y is preferably an alkylene group having from 1 to 20 carbon atoms, more preferably an alkylene group having from 1 to 15 carbon atoms, and still more preferably an alkylene group having from 1 to 10 carbon atoms.

Specific examples of an alkylene group represented by Y include a tetramethylene group, a hexamethylene group, a heptamethylene group, an octamethylene group, a nonamethylene group, a decamethylene group, an undecamethylene group, a dodecamethylene group, a 2-methylpentamethylene group, a 2-methylhexamethylene group, a 2-methylheptamethylene group, a 2-methyloctamethylene group, a 2-methylnonamethylene group, and a 2-methyldecamethylene group.

A cycloalkylene group represented by Y is preferably a cycloalkylene group having from 3 to 10 carbon atoms, and more preferably a cycloalkylene group having from 3 to 6 carbon atoms.

Specific examples of a cycloalkylene group represented by Y include a cyclopropylene group and a cyclohexylene group.

A unit structure included in a divalent group having a polyalkylene oxide structure represented by Y is preferably an alkylene oxide structure having from 1 to 10 carbon atoms, more preferably an alkylene oxide structure having from 1 to 8 carbon atoms, and still more preferably an alkylene oxide structure having from 1 to 4 carbon atoms. Among others, the polyalkylene oxide structure is preferably a polyethylene oxide structure or a polypropylene oxide structure. An alkylene group in an alkylene oxide structure may be linear or branched. The unit structure in a polyalkylene oxide structure may be of one kind or of two or more kinds.

A divalent group represented by Y may be a divalent group having a polysiloxane structure. Examples of the divalent group having a polysiloxane structure represented by Y include a divalent group having a polysiloxane structure in which a silicon atom in the polysiloxane structure is bonded to a hydrogen atom, an alkyl group having from 1 to 20 carbon atoms, or an aryl group having from 6 to 18 carbon atoms.

Specific examples of an alkyl group having from 1 to 20 carbon atoms bonded to a silicon atom in a polysiloxane structure include a methyl group, an ethyl group, an n-propyl group, an isopropyl group, an n-butyl group, a t-butyl group, an n-octyl group, a 2-ethylhexyl group, and an n-dodecyl group. Among them, a methyl group is preferable.

An aryl group having from 6 to 18 carbon atoms bonded to a silicon atom in a polysiloxane structure may be unsubstituted or substituted with a substituent. When an aryl group has a substituent, specific examples of the substituent include a halogen atom, an alkoxy group, and a hydroxy group. Specific examples of an aryl group having from 6 to 18 carbon atoms include a phenyl group, a naphthyl group, and a benzyl group. Among them, a phenyl group is preferable.

An alkyl group having from 1 to 20 carbon atoms or an aryl group having from 6 to 18 carbon atoms in a polysiloxane structure may be of one kind or of two or more kinds.

A silicon atom constituting a divalent group having a polysiloxane structure represented by Y may be bonded to an NH group in Formula (1) via an alkylene group such as a methylene group or an ethylene group, or an arylene group such as a phenylene group.

A group represented by Formula (G) is preferably a group represented by the following Formula (G′), a group represented by Formula (H) is preferably a group represented by the following Formula (H′), Formula (H″) or Formula (H″′), or from the viewpoint of a flexible skeleton and excellent adhesiveness, is more preferably a group represented by the following Formula (H′) or Formula (H″).

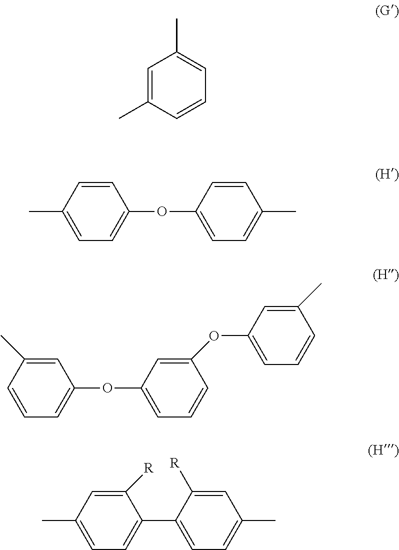

In Formula (H″′), each R independently represents an alkyl group, an alkoxy group, an alkyl halide group, a phenyl group, or a halogen atom. R is preferably an alkyl group, and more preferably a methyl group.

The combination of a tetravalent organic group represented by X and a divalent organic group represented by Y in Formula (1) is not particularly limited. Examples of the combination of a tetravalent organic group represented by X and a divalent organic group represented by Y include a combination of a group represented by Formula (E) for X and a group represented by Formula (H) for Y.

Each of R⁶ and R⁷ independently represents a hydrogen atom or a monovalent organic group and at least one of R⁶ and R⁷ has a polymerizable unsaturated bond. The monovalent organic group is preferably an aliphatic hydrocarbon group having from 1 to 4 carbon atoms or an organic group having an unsaturated double bond, and more preferably any of a group represented by the following Formula (2), an ethyl group, an isobutyl group, or a t-butyl group, and still more preferably includes an aliphatic hydrocarbon group having 1 or 2 carbon atoms or a group represented by the following Formula (2). In this case, at least one of R⁶ or R⁷ is the group represented by Formula (2).

In particular, when a monovalent organic group includes an organic group containing an unsaturated double bond, preferably a group represented by the following Formula (2), the i-ray transmittance tends to be high and a favorable cured product can be formed even when cured at low temperatures of 400° C. or less. Further, when the monovalent organic group includes an organic group containing an unsaturated double bond, preferably a group represented by the following Formula (2), at least a part of the unsaturated double bond moiety is eliminated by the action of a base or the like.

Specific examples of an aliphatic hydrocarbon group having from 1 to 4 carbon atoms include a methyl group, an ethyl group, an n-propyl group, an isopropyl group, an n-butyl group, and a t-butyl group, and among these, an ethyl group, an isobutyl group, or a t-butyl group is preferable.

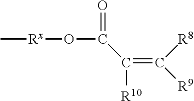

In Formula (2), each of R⁸ to R¹⁰ independently represents a hydrogen atom or an aliphatic hydrocarbon group having from 1 to 3 carbon atoms, and R^{x} represents a divalent linking group.

The number of carbon atoms of an aliphatic hydrocarbon group represented by R⁸ to R¹⁰ in Formula (2) is from 1 to 3, and is preferably 1 or 2. Specific examples of an aliphatic hydrocarbon group represented by R⁸ to R¹⁰ include a methyl group, an ethyl group, an n-propyl group, and an isopropyl group, and a methyl group is preferable.

As a combination of R⁸ to R¹⁰ in Formula (2), a combination where R⁸ and R⁹ are a hydrogen atom and R¹⁰ is a hydrogen atom or a methyl group is preferable.

R^{x} in Formula (2) is a divalent linking group, and preferably a hydrocarbon group having from 1 to 10 carbon atoms. Examples of a hydrocarbon group having from 1 to 10 carbon atoms include a linear or branched chain alkylene group.

The number of carbon atoms in R^{x} is preferably from 1 to 10, more preferably from 2 to 5, and still more preferably from 2 or 3.

In Formula (1), at least one of R⁶ or R⁷ is preferably a group represented by Formula (2), and each of R⁶ and R⁷ is more preferably a group represented by Formula (2).

When (A) a polyimide precursor includes a compound containing a structural unit represented by the above-described Formula (1), the ratio of R⁶ and R⁷ that are groups represented by Formula (2) to the total of R⁶ and R⁷ of all structural units contained in the compound is preferably 60% by mole or more, more preferably 70% by mole or more, and still more preferably 80% by mole or more. The upper limit is not particularly limited, and may be 100% by mole.

The above-described ratio may be from 0% by mole to less than 60% by mole.

A group represented by Formula (2) is preferably a group represented by the following Formula (2′).

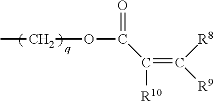

In Formula (2′), each of R⁸ to R¹⁰ independently represents a hydrogen atom or an aliphatic hydrocarbon group having from 1 to 3 carbon atoms, and q represents an integer from 1 to 10.

In Formula (2′), q is an integer from 1 to 10, and is preferably an integer from 2 to 5, and more preferably 2 or 3.

The content rate of a structural unit represented by Formula (1) in a compound containing the structural unit represented by Formula (1), with respect to the total structural unit, is preferably 60% by mole or more, more preferably 70% by mole or more, and still more preferably 80% by mole or more. The upper limit of the above-described content rate is not particularly limited, and may be 100% by mole.

(A) a polyimide precursor may be synthesized using tetracarboxylic dianhydride and a diamine compound. In this case, in Formula (1), X corresponds to a residue derived from tetracarboxylic dianhydride, and Y corresponds to a residue derived from a diamine compound. (A) the polyimide precursor may be synthesized using tetracarboxylic acid instead of tetracarboxylic dianhydride.

Specific examples of tetracarboxylic dianhydride include pyromellitic dianhydride, 2,3,6,7-naphthalenetetracarboxylic dianhydride, 3,3′,4,4′-biphenyltetracarboxylic dianhydride, 3,3′,4,4′-biphenyl ether tetracarboxylic dianhydride, 3,3′,4,4′-benzophenonetetracarboxylic dianhydride, 1,2,5,6-naphthalenetetracarboxylic dianhydride, 2,3,5,6-pyridinetetracarboxylic dianhydride, 1,4,5,8-naphthalenetetracarboxylic dianhydride, 3,4,9,10-perylenetetracarboxylic dianhydride, m-terphenyl-3,3′,4,4′-tetracarboxylic dianhydride, p-terphenyl-3,3′,4,4′-tetracarboxylic dianhydride, 1,1,4,4′-(4,4′-isopropylidenediphenoxy)diphthalic anhydride, 1,1,1,3,3,3-hexafluoro-2,2-bis(2,3-dicarboxyphenyl) propane dianhydride, 1,1,1,3,3,3-hexafluoro-2,2-bis(3,4-dicarboxyphenyl) propane dianhydride, 2,2-bis(2,3-dicarboxyphenyl) propane dianhydride, 2,2-bis(3,4-dicarboxyphenyl) propane dianhydride, 2,2-bis {4′-(2,3-dicarboxyphenoxy)phenyl}propane dianhydride, 2,2-bis {4′-(3,4-dicarboxyphenoxy)phenyl}propane dianhydride, 1,1,1,3,3,3-hexafluoro-2,2-bis {4′-(2,3-di carboxyphenoxy)phenyl}propane dianhydride, 1,1,1,3,3,3-hexafluoro-2,2-bis {4′-(3,4-dicarboxyphenoxy)phenyl}propane dianhydride, 4,4′-oxydiphthalic dianhydride, 4,4′-sulfonyldiphthalic dianhydride, 9,9-bis(3,4-dicarboxyphenyl) fluorene dianhydride, cyclopentanone bisspironorbornane tetracarboxylic dianhydride, and 2,2-bis {4-(4′-phenoxy)phenyl}propane tetracarboxylic dianhydride. Among these, 3,3′,4,4′-biphenyl ether tetracarboxylic acid dianhydride and 3,3′,4,4′-biphenyl tetracarboxylic acid dianhydride are preferable, and from the viewpoint of bonding at lower temperature, 3,3′,4,4′-biphenyl ether tetracarboxylic acid dianhydride is more preferable.

Tetracarboxylic dianhydride may be used singly, or two or more kinds thereof may be used in combination.

Specific examples of diamine compounds include 2,2′-dimethylbiphenyl-4,4′-diamine, 2,2′-bis(trifluoromethyl)-4,4′-diaminobiphenyl, 2,2′-difluoro-4,4′-diaminobiphenyl, p-phenylenediamine, m-phenylenediamine, p-xylylenediamine, m-xylylenediamine, 1,5-diaminonaphthalene, benzidine, 4,4′-diaminodiphenyl ether, 3,4′-diaminodiphenyl ether, 3,3′-diaminodiphenyl ether, 2,4′-diaminodiphenyl ether, 2,2′-diaminodiphenyl ether, 4,4′-diaminodiphenyl sulfone, 3,4′-diaminodiphenyl sulfone, 3,3′-diaminodiphenyl sulfone, 2,4′-diaminodiphenyl sulfone, 2,2′-diaminodiphenyl sulfone, 4,4′-diaminodiphenyl sulfide, 3,4′-diaminodiphenyl sulfide, 3,3′-diaminodiphenyl sulfide, 2,4′-diaminodiphenyl sulfide, 2,2′-diaminodiphenyl sulfide, o-tolidine, o-tolysine sulfone, 4,4′-methylenebis(2,6-diethylaniline), 4,4′-methylenebis(2,6-diisopropylaniline), 2,4-diaminomesitylene, 1,5-diaminonaphthalene, 4,4′-benzophenonediamine, bis-{4-(4′-aminophenoxy)phenyl}sulfone, 2,2-bis {4-(4′-aminophenoxy)phenyl}propane, 3,3′-dimethyl-4,4′-diaminodiphenylmethane, 3,3′,5,5′-tetramethyl-4,4′-diaminodiphenylmethane, bis {4-(3′-aminophenoxy)phenyl}sulfone, 2,2-bis(4-aminophenyl) propane, 9,9-bis(4-aminophenyl) fluorene, 1,3-bis(3-aminophenoxy)benzene, 1,4-diaminobutane, 1,6-diaminohexane, 1,7-diaminoheptane, 1,8-diaminooctane, 1,9-diaminononane, 1,10-diaminodecane, 1,11-diaminoundecane, 1,12-diaminododecane, 2-methyl-1,5-diaminopentane, 2-methyl-1,6-diaminohexane, 2-methyl-1,7-diaminoheptane, 2-methyl-1,8-diaminooctane, 2-methyl-1,9-diaminononane, 2-methyl-1,10-diaminodecane, 1,4-cyclohexanediamine, 1,3-cyclohexanediamine, and diaminopolysiloxane. As the diamine compound, 2,2′-dimethylbiphenyl-4,4′-diamine, m-phenylenediamine, 4,4′-diaminodiphenyl ether and 1,3-bis(3-aminophenoxy)benzene are preferable. Among these, 4,4′-diaminodiphenyl ether, 1,3-bis(3-aminophenoxy)benzene and 2,2-bis {4-(4′-aminophenoxy)phenyl}propane are more preferable from the viewpoint of having a flexible skeleton and excellent adhesiveness.

A diamine compound may be used singly, or two or more kinds thereof may be used in combination.

A compound having a structural unit represented by Formula (1) and at least one of R⁶ or R⁷ in Formula (1) is a monovalent organic group can be obtained, for example, by the following method (a) or (b).

(a) Tetracarboxylic dianhydride (preferably tetracarboxylic dianhydride represented by Formula (8) below) is reacted with a compound represented by R—OH in an organic solvent to form a diester derivative, followed by a condensation reaction of the diester derivative with a diamine compound represented by H₂N—Y—NH₂.

(b) A polyamide acid solution is obtained by reacting tetracarboxylic dianhydride with a diamine compound represented by H₂N—Y—NH₂ in an organic solvent, and a compound represented by R—OH is added to the polyamide acid solution to introduce an ester group by reaction in an organic solvent.

Here, Y in a diamine compound represented by H₂N—Y—NH₂ is the same as Y in Formula (1), and specific examples and preferable examples thereof are also the same as those in Formula (1). R in a compound represented by R—OH represents a monovalent organic group, and specific examples and preferable examples thereof are the same as those for R⁶ and R⁷ in Formula (1).

Each of a tetracarboxylic dianhydride represented by Formula (8), a diamine compound represented by H₂N—Y—NH₂, and a compound represented by R—OH may be used singly, or two or more kinds thereof may be used in combination.

Examples of the above-described organic solvent include N-methyl-2-pyrrolidone, y-butyrolactone, dimethoxyimidazolidinone, and 3-methoxy-N,N-dimethylpropionamide, and among these, 3-methoxy-N,N-dimethylpropionamide is preferable.

A polyimide precursor may be synthesized by allowing a dehydration condensation agent to act on a polyamide acid solution together with a compound represented by R—OH. The dehydration condensation agent preferably includes at least one selected from the group consisting of trifluoroacetic anhydride, N,N′-dicyclohexylcarbodiimide (DCC), and 1,3-diisopropylcarbodiimide (DIC).

The above-described compound in (A) a polyimide precursor can be obtained by acting a compound represented by R—OH on tetracarboxylic dianhydride represented by the following Formula (8) to obtain a diester derivative, then converting the diester derivative to an acid chloride by acting a chlorinating agent such as thionyl chloride, and then reacting the acid chloride with a diamine compound represented by H₂N—Y—NH₂.

The above-described compound in (A) a polyimide precursor can be obtained by allowing a compound represented by R—OH to act on tetracarboxylic dianhydride represented by the following Formula (8) to obtain a diester derivative, and then reacting the diester derivative with a diamine compound represented by H₂N—Y—NH₂ in the presence of a carbodiimide compound.

The above-described compound in (A) a polyimide precursor can be obtained by reacting tetracarboxylic dianhydride represented by the following Formula (8) with a diamine compound represented by H₂N—Y—NH₂ to obtain polyamide acid, followed by isoimidation of the polyamide acid in the presence of a dehydration condensation agent such as trifluoroacetic anhydride, and then by action of a compound represented by R—OH. Alternatively, a compound represented by R—OH may be allowed to act on a portion of tetracarboxylic dianhydride in advance, and the partially esterified tetracarboxylic dianhydride may react with a diamine compound represented by H₂N—Y—NH₂.

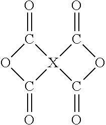

In Formula (8), X is the same as X in Formula (1), and specific examples and preferable examples thereof are also the same.

A compound represented by R—OH used in synthesizing the above-described compound included in (A) a polyimide precursor may be a compound in which a hydroxy group is bonded to R^{X} of a group represented by Formula (2), a compound in which a hydroxy group is bonded to a terminal methylene group of a group represented by Formula (2′), or the like. Specific examples of a compound represented by R—OH include methanol, ethanol, n-propanol, isopropanol, n-butanol, 2-hydroxyethyl methacrylate, 2-hydroxyethyl acrylate, 2-hydroxyethyl methacrylate, 2-hydroxypropyl acrylate, 2-hydroxypropyl methacrylate, 2-hydroxybutyl acrylate, 2-hydroxybutyl methacrylate, 4-hydroxybutyl acrylate, and 4-hydroxybutyl methacrylate. Among them, 2-hydroxyethyl methacrylate or 2-hydroxyethyl acrylate is preferable.

The molecular weight of (A) a polyimide precursor is not particularly limited, and for example, the weight average molecular weight is preferably from 10,000 to 200,000, and more preferably from 10,000 to 100,000.

The weight average molecular weight can be measured, for example, by gel permeation chromatography, and can be obtained by conversion using a standard polystyrene calibration curve.

The material for forming an insulating film of the disclosure may further include a dicarboxylic acid, and (A) a polyimide precursor in the material for forming an insulating film may have a structure in which a portion of an amino group in (A) the polyimide precursor is reacted with a carboxy group in the dicarboxylic acid. For example, during synthesis of a polyimide precursor, a portion of an amino group in a diamine compound may be reacted with a carboxy group in a dicarboxylic acid.

A dicarboxylic acid may be a dicarboxylic acid containing a (meth)acrylic group, for example, a dicarboxylic acid represented by the following Formula. In this case, when synthesizing (A) a polyimide precursor, by reacting a portion of an amino group of a diamine compound with a carboxy group of a dicarboxylic acid, a methacrylic group derived from the dicarboxylic acid can be introduced into (A) the polyimide precursor.

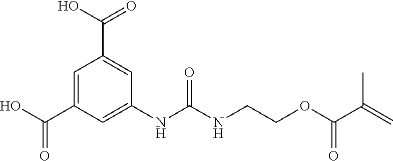 [SMILES: C=C(C)C(=O)OCCNC(=O)Nc1cc(C(=O)O)cc(C(=O)O)c1]

The material for forming an insulating film of the disclosure may contain a polyimide resin in addition to (A) the polyimide precursor. By combining a polyimide precursor and a polyimide resin, it is possible to suppress the generation of volatiles due to dehydration cyclization during imide ring formation, and therefore the occurrence of voids tends to be suppressed. The polyimide resin referred to here refers to a resin having an imide skeleton in all or part of the resin skeleton. The polyimide resin is preferably soluble in a solvent in a material for forming an insulating film using a polyimide precursor.

A polyimide resin is not particularly limited as long as the resin is a high molecular weight compound containing a plurality of structural units including an imide bond, for example, a compound containing a structural unit represented by the following Formula (X) is preferable. As a result, a semiconductor device provided with an insulating film exhibiting high reliability tends to be obtained.

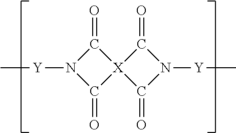

In Formula (X), X represents a tetravalent organic group, and Y represents a divalent organic group. Preferable examples of substituents X and Y in Formula (X) are the same as preferable examples of substituents X and Y in Formula (1) described above.

When the material for forming an insulating film of the disclosure contains a polyimide resin, the ratio of the polyimide resin to the total of the polyimide precursor and the polyimide resin may be from 15% by mass to 50% by mass, or from 10% by mass to 20% by mass.

The material for forming an insulating film of the disclosure may contain another resin component other than (A) the polyimide precursor. From the viewpoint of heat resistance, examples of the other resin include a novolac resin, an acrylic resin, a polyether-nitrile resin, a polyethersulfone resin, an epoxy resin, a polyethylene terephthalate resin, a polyethylene naphthalate resin, or a polyvinyl chloride resin. The other resin may be used singly, or two or more kinds thereof may be used in combination.

In the material for forming an insulating film of the disclosure, the content ratio of (A) the polyimide precursor to the total resin component is preferably from 50% by mass to 100% by mass, more preferably from 70% by mass to 100% by mass, and still more preferably from 90% by mass to 100% by mass.

The material for forming an insulating film of the disclosure may or may not contain a resin component such as a cyclic olefin resin such as benzocyclobutene, and an epoxy resin. From the viewpoint of achieving superior heat resistance and mechanical properties of the insulating film and of suitably suppressing poor bonding between the insulating film and an electrode and poor bonding between insulating films when hybrid bonding is performed, the content rate of the cyclic olefin resin and the content rate of the epoxy resin are each independently preferably 30% by mass or less, more preferably from 0% by mass to 10% by mass, and still more preferably from 0% by mass to 5% by mass, with respect to the total amount of the material for forming an insulating film of the disclosure.

### ((B) Solvent)

The material for forming an insulating film of the disclosure contains (B) a solvent (hereinafter, also referred to as “(B) component”).

(B) the component is not particularly limited and examples thereof include an ester-based solvent, a ketone-based solvent, a carbonate-based solvent, a heterocyclic compound-based solvent, and an amide-based solvent

The ester-based solvent, ketone-based solvent, carbonate-based solvent, and amide-based solvent may each independently have a cyclic structure or may not have a cyclic structure.

(B) the component may be used alone, or in combination of two or more kinds.

From the viewpoint of photosensitivity of the material for forming an insulating film, (B) the component preferably contains a non-amide based solvent other than an amide-based solvent, and (B) the component more preferably consists of a non-amide solvent without containing an amide-based solvent.

The non-amide solvent is not particularly limited as long as a compound not containing an amide group, and examples thereof include the aforementioned ester-based solvent, ketone-based solvent, carbonate-based solvent, and heterocyclic compound-based solvent. Among them, the non-amide solvent is preferably an ester-based solvent such as a cyclic ester compound.

For example, (B) the component may contain at least one selected from the group consisting of compounds represented by the following formula (3) to formula (10).

(B) the component may be used alone, or in combination of two or more kinds.

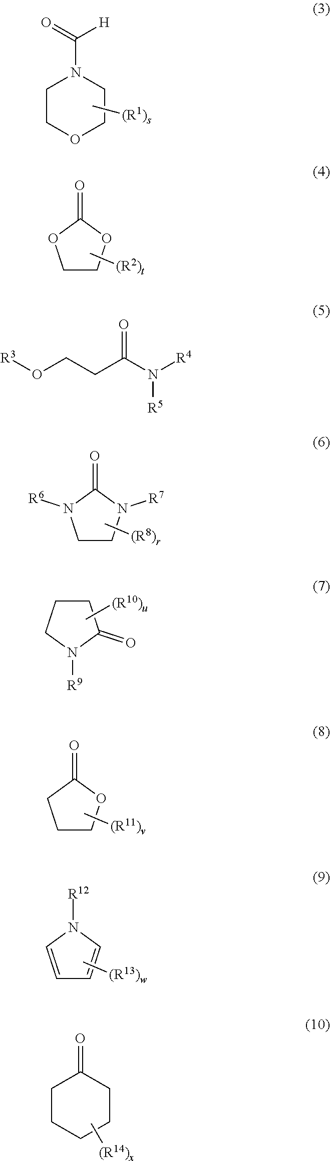

In Formulas (3) to (10), each of R¹, R², R⁸, R¹⁰, R¹¹, R¹³, and R¹⁴ is each independently an alkyl group having from 1 to 4 carbon atoms, and each of R³ to R⁷, R⁹ and R¹² is each independently a hydrogen atom or an alkyl group having from 1 to 4 carbon atoms. s is an integer from 0 to 8, t is an integer from 0 to 4, r is an integer from 0 to 4, and u is an integer from 0 to 3, v is an integer from 0 to 3, w is an integer from 0 to 4 and x is an integer from 0 to 5.

In Formula (3), s is preferably 0.

In Formula (4), an alkyl group having from 1 to 4 carbon atoms in R² is preferably a methyl group or an ethyl group. t is preferably 0, 1 or 2, and more preferably 1.

In Formula (5), an alkyl group having from 1 to 4 carbon atoms in R³ is preferably a methyl group, an ethyl group, a propyl group, or a butyl group. An alkyl group having from 1 to 4 carbon atoms in R⁴ and R⁵ is preferably a methyl group or an ethyl group.

In Formula (6), an alkyl group having from 1 to 4 carbon atoms in R⁶ to R⁸ is preferably a methyl group or an ethyl group. r is preferably 0 or 1, and more preferably 0.

In Formula (7), an alkyl group having from 1 to 4 carbon atoms in R⁹ and R¹⁰ is preferably a methyl group or an ethyl group. u is preferably 0 or 1, and more preferably 0.

In Formula (8), an alkyl group having from 1 to 4 carbon atoms in R¹¹ is preferably a methyl group or an ethyl group. u is preferably 0 or 1, and more preferably 0.

In Formula (9), an alkyl group having from 1 to 4 carbon atoms in R¹² is preferably a methyl group or an ethyl group. An alkyl group having from 1 to 4 carbon atoms in R¹³ is preferably a methyl group or an ethyl group. w is preferably 0 or 1, and more preferably 0.

In Formula (10), an alkyl group having from 1 to 4 carbon atoms in R¹⁴ is preferably a methyl group or an ethyl group. x is preferably 0 or 1, and more preferably 0.

Specific examples of the component (B) include the following compounds: The component (B) may contain y-butyrolactone or cyclohexanone, or may contain y-butyrolactone, for example, from the viewpoint of increasing i-line transmittance.

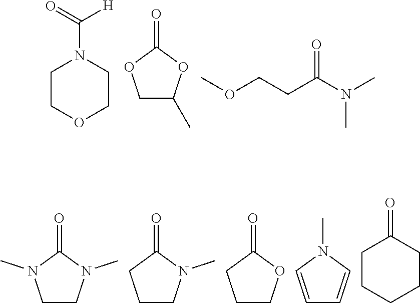

In the material for forming an insulating film of the disclosure, from the viewpoint of reducing toxicity such as reproductive toxicity, the content of N-methyl-2-pyrrolidone (NMP) may be 1% by mass or less with respect to the total amount of the material for forming an insulating film, and may be 3% by mass or less with respect to the total amount of (A) a component.

In the material for forming an insulating film of the disclosure, the content of (B) the component is preferably from 1 part by mass to 10000 parts by mass, and more preferably from 50 parts by mass to 10000 parts by mass with respect to 100 parts by mass of (A) the component.

### ((C) Filler)

A material for forming a hybrid insulating film of the disclosure contain (C) a filler (also referred to as “(C) component”). (C) the component may be an organic filler, may be an inorganic filler or may be an inorganic-organic composite filler.

(C) the filler may be used alone, or in combination of two or more kinds.

Examples of the organic filler include a polyethylene fiber, a polypropylene fiber, a polyester fiber, a polyamide fiber, a fluorine fiber, ebonite powder, a thermosetting resin hollow sphere, an epoxy resin filler, a silicone filler, a saran hollow sphere, shellac, wood flour, cork powder, a polyvinyl alcohol fiber, cellulose powder, and wood pulp. Among these, an epoxy resin filler, a silicone filler, a thermosetting resin hollow particle, and a fluorine fiber are particularly preferable due to their excellent heat resistance and mechanical properties.

Examples of the inorganic filler include silica, alumina, aluminum hydroxide, magnesium hydroxide, calcium carbonate, magnesium carbonate, calcium silicate, magnesium silicate, zirconium silicate, calcium oxide, magnesium oxide, titanium oxide, silicon nitride, aluminum nitride, boron nitride, calcium titanate, barium titanate, beryllia, zirconia, zircon, forsterite, steatite, spinel, mullite, titania, talc, clay, and mica. Among these, silica and alumina are particularly preferable, and silica is more preferable.

When (C) the component is particulate, the volume average particle size is not particularly limited. For example, the volume average particle size is preferably from 10 nm to 1 μm, more preferably from 10 nm to 500 nm, from the viewpoint of filler dispersibility, still more preferably from 10 nm to 100 nm, and particularly preferably from 15 nm to 50 nm.

The volume average particle size of (C) the component is a value measured as the volume average particle size (D50) using a laser diffraction scattering particle size distribution measuring device.

The volume average particle size of (C) the component in the material for forming an insulating film or insulating film can be measured by known methods. For example, (C) the component (preferably an inorganic filler) is extracted from the material for forming an insulating film or insulating film using an organic solvent, nitric acid, aqua regia, or the like, and then thoroughly dispersed using an ultrasonic disperser or the like to prepare a dispersion. Using this dispersion, the volume average particle size of (C) the component (preferably an inorganic filler) can be measured from the volume-based particle size distribution measured using a laser diffraction/scattering particle size distribution analyzer. Alternatively, the insulating film can be embedded in a transparent epoxy resin or the like, polished, and the resulting cross-section observed using a scanning electron microscope to obtain a volume-based particle size distribution, from which the volume average particle size of (C) the component can be measured. Furthermore, the volume average particle size of (C) the component can also be measured by continuously observing two-dimensional cross-sections of the insulating film using an FIB device (focused ion beam SEM) or the like, followed by three-dimensional structural analysis.

(C) the component is preferably subjected to a surface treatment. Thereby the dispersibility of (C) the component in the material for forming an insulating film of the disclosure tends to be improved, and as a result, tends to have good photosensitive properties.

The material for forming an insulating film of the disclosure preferably contains a surface treated inorganic filler, and more preferably contains at least one of a surface treated silica or a surface treated alumina.

From the viewpoint of improving the dispersibility of (C) the component, examples of the surface treatment include a hydrophobization treatment. A commercially available filler may be used as (C) the component that has been surface-treated. Alternatively, (C) the component that is not surface-treated, may be surface-treated using a surface treatment agent such as the coupling agent described below.

In the material for forming an insulating film, the content of (C) the component may be from 5 parts by mass to 200 parts by mass, may be from 10 parts by mass to 150 parts by mass, may be from 10 parts by mass to 100 parts by mass, may be from 15 parts by mass to 50 parts by mass or may be from 25 parts by mass to 50 parts by mass.

When a filler dispersed to a dispersion solvent is used, the content of (C) the component means the content of the filler, which is the solid content excluding the dispersion solvent.

(C) the component may be a filler dispersed in a dispersion solvent from the viewpoint of preventing aggregation. The dispersion solvent is not particularly limited, and examples thereof include known solvents such as cyclohexanone and dimethylacetamide.

The material for forming an insulating film may optionally contain at least one of (D) a polymerizable monomer, (E) a photopolymerization initiator, (F) a sensitizer, (G) a coupling agent, a thermal polymerization initiator, a polymerization inhibitor, an antioxidant, a surfactant, a leveling agent, a rust inhibitor, a nitrogen-containing compound, or a dicarboxylic acid.

The material for forming an insulating film may contain (D) a polymerizable monomer and (E) a photopolymerization initiator.

### ((D) Polymerizable Monomer)

The material for forming an insulating film may contain (D) a polymerizable monomer (hereinafter also referred to as “(D) component”). (D) the component preferably contains at least one group containing a polymerizable unsaturated double bond, and from the viewpoint of suitable polymerization by combination with (E) a photoinitiator, the component more preferably contains at least one (meth)acrylic group. From the viewpoint of improving crosslink density and photosensitivity, it is preferable to have from 2 to 6 groups containing a polymerizable unsaturated double bond, and it is more preferable to have from 2 to 4 such groups.

The polymerizable monomer may be used singly, or two or more kinds thereof may be used in combination.

The polymerizable monomer containing a (meth)acrylic group is not particularly limited, and examples thereof include diethylene glycol diacrylate, triethylene glycol diacrylate, tetraethylene glycol diacrylate, diethylene glycol dimethacrylate, triethylene glycol dimethacrylate, tetraethylene glycol dimethacrylate, 1,4-butanediol diacrylate, 1,6-hexanediol diacrylate, 1,4-butanediol dimethacrylate, 1,6-hexanediol dimethacrylate, trimethylolpropane diacrylate, trimethylolpropane triacrylate, trimethylolpropane dimethacrylate, trimethylolpropane trimethacrylate, pentaerythritol triacrylate, pentaerythritol tetra arylate, pentaerythritol trimethacrylate, pentaerythritol tetramethacrylate, dipentaerythritol hexaacrylate, dipentaerythritol hexamethacrylate, ethoxylated pentaerythritol tetraacrylate, ethoxylated isocyanuric acid triacrylate, ethoxylated isocyanuric acid trimethacrylate, acryloyloxyethyl isocyanurate, methacryloyloxyethyl isocyanurate, 2-hydroxyethyl (meth)acrylate, 1,3-bis((meth)acryloyloxy)-2-hydroxypropane, ethylene oxide (EO)-modified bisphenol A diacrylate, and ethylene oxide (EO)-modified bisphenol A dimethacrylate.

The polymerizable monomer containing a (meth)acrylic group may be tetraethylene glycol dimethacrylate, ethoxylated pentaerythritol tetraacrylate, or the mixture thereof.

A polymerizable monomer other than polymerizable monomer containing a (meth)acrylic group is not particularly limited, and examples thereof include styrene, divinylbenzene, 4-vinyltoluene, 4-vinylpyridine, N-vinylpyrrolidone, methylenebisacrylamide, N,N-dimethylacrylamide, and N-methylolacrylamide.

(D) the component is not limited to a compound containing a group containing a polymerizable unsaturated double bond and may be a compound containing a polymerizable group (for example, oxirane ring) other than an unsaturated double bond.

When the material for forming an insulating film of the disclosure contains (D) the component, the content of (D) the component is not particularly limited and it is preferably from 1 part by mass to 100 parts by mass, more preferably from 1 part by mass to 75 parts by mass, and still more preferably from 1 part by mass to 50 parts by mass.

When (D) the component is a mixture of tetraethylene glycol dimethacrylate (D1) and ethoxylated pentaerythritol tetraacrylate (D2), a mass ratio (D2/D1) of D2 with respect to D1 may be from 50/100 to 100/100, or may be from 60/100 to 90/100.

### ((E) Photopolymerization Initiator)

The material for forming an insulating film of the disclosure may contain (E) a photopolymerization initiator (hereinafter, also referred to as “(E) component”).

(E) the component is not particularly limited and examples thereof include an oxime compound such as 1-phenyl-1,2-butanedione-2-(O-methoxycarbonyl) oxime, 1-phenyl-1,2-propanedione-2-(O-methoxycarbonyl) oxime, 1-phenyl-1,2-propane dione-2-(O-ethoxycarbonyl) oxime, 1-phenyl-1,2-propanedione-2-(O-benzoyl) oxime, 1,3-diphenylpropanetrione-2-(O-ethoxycarbonyl) oxime, 1-phenyl-3-ethoxypropanetrione-2-(O-benzoyl) oxime, 1-[4-(phenylthio)phenyl] octane-1,2-dione-2-(O-benzoyloxime), O-acetyl-1-[6-(2-methylbenzoyl)-9-ethyl-9H-carbazol-3-yl]ethanone oxime, or 1-[4-(4-hydroxyethyloxy-phenylthio)phenyl]-1,2-propanedione-2-(O-acetyloxime);
an acetophenone derivative such as acetophenone, 2,2-diethoxyacetophenone, 3′-methylacetophenone, 2,2-dimethoxy-2-phenylacetophenone, 2-hydroxy-2-methylpropiophenone, 4′-(methylthio)-a-morpholino-a-methylpropiophenone, or 1-hydroxycyclohexyl phenyl ketone;
a thioxanthone derivative such as thioxanthone, 2-methylthioxanthone, 2-isopropylthioxanthone, 2-chlorothioxanthone, or diethylthioxanthone;
a benzyl derivative such as benzil, benzil dimethyl ketal, or benzyl-β-methoxyethyl acetal;
a benzoin derivative such as benzoin, benzoin methyl ether, benzoin ethyl ether, benzoin phenyl ether, methylbenzoin, ethylbenzoin, or propylbenzoin;
an N-arylglycine such as N-phenylglycine;
a peroxide such as benzoyl perchloride;
an aromatic biimidazole such as 2-(o-chlorophenyl)-4,5-diphenylimidazole dimer, 2-(o-fluorophenyl)-4,5-diphenylimidazole dimer, or 2-(o- or p-methoxyphenyl)-4,5-diphenylimidazole dimer; and
an acylphosphine oxide derivative such as 2,4,6-trimethylbenzoyl-diphenylphosphine oxide or bis(2,4,6-trimethylbenzoyl)phenylphosphine oxide, Irgacure OXE03 (manufactured by BASF), and Irgacure OXE04 (manufactured by BASF).

From the viewpoints of achieving excellent exposure sensitivity and suppressing the occurrence of a void during bonding, (E) the component preferably contains an oxime compound.

(E) the component may be used singly, or two or more kinds thereof may be used in combination.

The content rate of the oxime compound with respect to the total amount of (E) the component is preferably 60% by mass or more, more preferably 80% by mass or more, still more preferably 90% by mass or more, and particularly preferably 95% by mass or more.

The total amount of (E) the component is preferably from 0.1 parts by mass to 20 parts by mass, more preferably from 1 part by mass to 20 parts by mass and still more preferably from 2 parts by mass to 10 parts by mass.

### ((F) Sensitizer)

The material for forming an insulating film may contain (F) a sensitizer. Examples of (F) the sensitizer include benzophenone and a benzophenone derivative such as N,N′-tetramethyl-4,4′-diaminobenzophenone (Michler's ketone), N,N′-tetraethyl-4,4′-diaminobenzophenone, 4-methoxy-4′-dimethylaminobenzophenone, 4-chlorobenzophenone, 4,4′-dimethoxybenzophenone, 4,4′-diaminobenzophenone, 4,4′-bis(diethylamino)benzophenone, methyl o-benzoylbenzoate, 4-benzoyl-4′-methyldiphenyl ketone, dibenzyl ketone, and fluorenone.

(F) the component may be used singly, or two or more kinds thereof may be used in combination.

When the material for forming an insulating film of the disclosure contain (F) the component, the content of (F) the component is not particularly limited and the content is preferably from 0.01 parts by mass to 3 parts by mass, more preferably from 0.1 parts by mass to 1 part by mass.

### ((G) Coupling Agent)

The material for forming an insulating film of the disclosure may contain (G) a coupling agent. Examples of (G) the coupling agent is not particularly limited, and examples thereof include a silane coupling agent such as 3-aminopropyltrimethoxysilane, N-(2-aminoethyl)-3-aminopropylmethyldimethoxysilane, 3-glycidoxypropylmethyldimethoxysilane, 3-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl) succinimide, N-[3-(triethoxysilyl) propyl] phthalamic acid, benzophenone-3,3′-bis(N-[3-triethoxysilyl]propylamido)-4,4′-dicarboxylic acid, benzene-1,4-bis(N-[3-triethoxysilyl]propylamido)-2,5-dicarboxylic acid, 3-(triethoxysilyl) propyl succinic anhydride, N-phenylaminopropyltrimethoxysilane, N,N′-bis(2-hydroxyethyl)-3-aminopropyltriethoxysilane, or 3-ureidopropyltriethoxysilane; or an aluminum-based adhesion promoter such as aluminum tris(ethylacetoacetate), aluminum tris(acetylacetonate), or ethylacetoacetate aluminum diisopropylate.

(G) the component may be used singly, or two or more kinds thereof may be used in combination.

These coupling agents are used for a surface treatment to the aforementioned (C) component.

A method of preparing a material for forming an insulating film of the disclosure is not particularly limited and each of the components may be mixed.

### <Semiconductor Device>

A semiconductor device of the disclosure includes a first semiconductor substrate including a first substrate body, and a first organic insulating film and a first electrode provided on one side of the first substrate body; and a semiconductor chip including a semiconductor chip substrate body, and a second organic insulating film and a second electrode provided on one side of the semiconductor chip substrate body, and the first organic insulating film of the first semiconductor substrate and the second organic insulating film of the semiconductor chip are bonded, and the first electrode of the first semiconductor substrate and the second electrode of the semiconductor chip are bonded, at least one of the first organic insulating film or the second organic insulating film is an insulating film obtained by curing a photosensitive material for forming an insulating film that contains (A) a polyimide precursor, and (C) a filler and that has photosensitivity, and an i-line transmittance of the insulating film is from 5% to 40%.

In the semiconductor device of the disclosure, at least one of the first organic insulating film or the second organic insulating film is an insulating film obtained by curing a photosensitive material for forming an insulating film that contains (A) a polyimide precursor, and (C) a filler and that has photosensitivity. Further, an i-line transmittance of the insulating film is from 5% to 40%. Thereby, the semiconductor device of the disclosure includes an insulating film, which is formed by the material for forming an insulating film that has photosensitivity, and in which the linear expansion coefficient is reduced.

The material for forming an insulating film used for the semiconductor device of the disclosure includes (A) a polyimide precursor and (C) a filler, and has photosensitivity and the i-line transmittance is from 5% to 40%. For example, the material for forming an insulating film may be the material for forming an insulating film of the disclosure.

Further, the semiconductor device of the disclosure, for example, can be manufactured by a method of manufacturing a semiconductor device as shown below.

The i-line transmittance of the insulating film formed by a material for forming an insulating film used for the semiconductor device of the disclosure is from 5% to 40%, for example, may be from 10% to 40%, or may be from 12% to 30%.

### <Method of Manufacturing Semiconductor Device>

In a method of manufacturing a semiconductor device of the disclosure, the aforementioned material for forming an insulating film of the disclosure is used to prepare an organic insulating film at least one of the first organic insulating film or the second organic insulating film, and the first organic insulating film and the second organic insulating film are bonded to form the semiconductor device. More specifically, the semiconductor device can be produced through the following processes (1) to (5).

Process (1) A first semiconductor substrate including a first substrate body and the first organic insulating film and a first electrode provided on one side of the first substrate body is prepared.

Process (2) A second semiconductor substrate including a second substrate body and the second organic insulating film and a plurality of second electrodes provided on one side of the second substrate body is prepared.

Process (3) The second semiconductor substrate is broken into pieces to obtain a plurality of semiconductor chips each having the second organic insulating film and at least one of the second electrodes.

Process (4) The first organic insulating film of the first semiconductor substrate and the second organic insulating film of the semiconductor chip are attached to each other.

Process (5) The first electrode of the first semiconductor substrate and the second electrode of the semiconductor chip are bonded together.

The process (1) may include a process of forming a via by applying a material for forming an insulating film on a first substrate body and then removing a portion of the material for forming an insulating film applied on the first substrate body, and
a process of preparing a first semiconductor substrate including a first organic insulating film and a first electrode provided on one side of the first substrate body, by curing the material for forming an insulating film in which the via is formed on the first substrate body to form the first organic insulating film and filing an electrode material into the via to form the first electrode.

The process (2) may include a process of forming a via by applying a material for forming an insulating film on a second substrate body and then removing a portion of the material for forming an insulating film applied on the second substrate body, and
a process of preparing a second semiconductor substrate including a second organic insulating film and a second electrode provided on one side of the second substrate body, by curing the material for forming an insulating film in which the via is formed on the second substrate body to form the second organic insulating film and filing an electrode material into the via to form the second electrode.

Alternatively, the process (1) may include a process of forming a first electrode on a first substrate body and then forming a first organic insulating film around the first electrode, thereby preparing a first semiconductor substrate having the first organic insulating film and the first electrode provided on one surface of the first substrate body.

The process (2) may include a process of forming a second electrode on a second substrate body and then forming a second organic insulating film around the second electrode, thereby preparing a second semiconductor substrate having the second organic insulating film and the second electrode provided on one surface of the second substrate body.

Hereinafter, with reference to the drawings, one embodiment of the semiconductor device of the disclosure and one embodiment of the method of manufacturing a semiconductor device of the disclosure will be described in detail. In the following description, an identical or equivalent portion is indicated with the same symbol, and a redundant description will be omitted. Unless otherwise specified, the positional relationships of top, bottom, left, right, and the like are based on the positional relationships illustrated in the drawings. Furthermore, the dimensional ratios in the drawings are not limited to the ratios illustrated in the drawings.

### (One Example of Semiconductor Device)

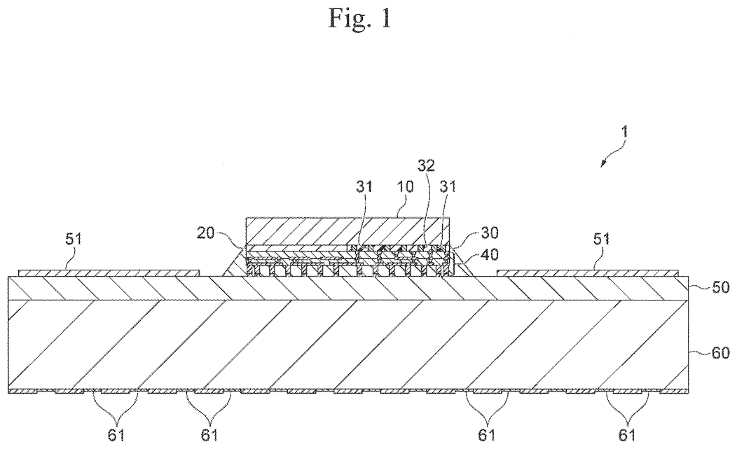

FIG. 1 is a schematic sectional view of an example of the semiconductor device of the disclosure. As illustrated in FIG. 1, a semiconductor device 1 is one example of a semiconductor package, and includes a first semiconductor chip 10 (first semiconductor substrate), a second semiconductor chip 20 (semiconductor chip), a pillar portion 30, a rewiring layer 40, a substrate 50, and a circuit board 60.

The first semiconductor chip 10 is a semiconductor chip such as a large scale integrated circuit (LSI) chip or a complementary metal oxide semiconductor (CMOS) sensor, and has a three-dimensional mounting structure in which the second semiconductor chip 20 is mounted downward. The second semiconductor chip 20 is a semiconductor chip such as an LSI or a memory, and is a chip component with a smaller area in plan view than the first semiconductor chip 10. The second semiconductor chip 20 is chip-to-chip (C2C) bonded to the backside of the first semiconductor chip 10. The first semiconductor chip 10 and the second semiconductor chip 20 are micro bonded by hybrid bonding, the details of which are described below, to each terminal electrode and the surrounding insulating film firmly and without misalignment.

The pillar portion 30 is a connecting portion in which a plurality of pillars 31 formed of a metal such as copper (Cu) are sealed by a resin 32. The plurality of pillars 31 are conductive members extending from the top surface to the bottom surface of the pillar portion 30. The plurality of pillars 31 may have a cylindrical shape with a diameter of from 3 μm to 20 μm (in one example, 5 μm in diameter), for example, and may be arranged in such a manner that the distance between centers of the pillars 31 is 15 μm or smaller. The plurality of pillars 31 make flip chip connections between a terminal electrode on the bottom side of the first semiconductor chip 10 and a terminal electrode on the top side of the rewiring layer 40. By using the pillar portion 30, the semiconductor device 1 can form a connecting electrode without using a technique called through mold via (TMV), in which a hole is drilled in a mold and a solder connection is made. The pillar portion 30, for example, has the same thickness as the second semiconductor chip 20, and is positioned horizontally to the side of the second semiconductor chip 20. A plurality of solder balls may be arranged instead of the pillar portions 30, and the solder balls may electrically connect a terminal electrode on the bottom side of the first semiconductor chip 10 to a terminal electrode on the top side of the rewiring layer 40.

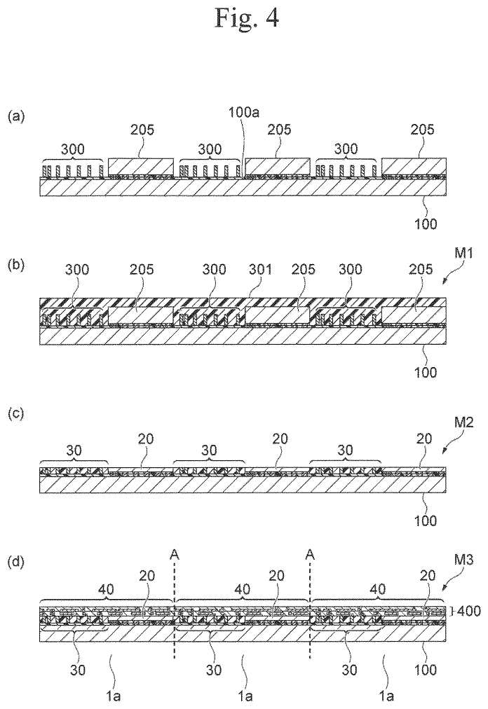

The rewiring layer 40 is a wiring layer having a function of terminal pitch conversion, which is a function of a package substrate, and is a layer in which a rewiring pattern is formed with polyimide, copper wiring, and the like on an insulating film on the bottom side of the second semiconductor chip 20 and on the underside of the pillar portion 30. The rewiring layer 40 is formed in a state in which the first semiconductor chip 10 (the first semiconductor substrate 100), the second semiconductor chip 20, and the like are inverted upside down (see (d) of FIG. 4).

The rewiring layer 40 electrically connects a terminal electrode on the underside of the second semiconductor chip 20 and a terminal electrode of the first semiconductor chip 10 via the pillar portion 30 to a terminal electrode of the substrate 50. The terminal pitch of the substrate 50 is wider than the terminal pitch of a pillar 31 and the terminal pitch of the second semiconductor chip 20. Various electronic components 51 may be mounted on the substrate 50. When there is a large gap in the terminal pitch between the rewiring layer 40 and the substrate 50, an inorganic interposer or the like may be used between the rewiring layer 40 and the substrate 50 for electrical connection between the rewiring layer 40 and the substrate 50.

Circuit board 60 is a substrate including a first semiconductor chip 10 and a second semiconductor chip 20 mounted thereon and including a plurality of through-hole electrodes therein that are electrically connected to the substrate 50 connected to the first semiconductor chip 10, the second semiconductor chip 20, the electronic components 51, and the like. In the circuit board 60, each terminal electrode of the first semiconductor chip 10 and the second semiconductor chip 20 is electrically connected to a terminal electrode 61 provided on the back surface of the circuit board 60 by the plurality of through-hole electrodes.

### (One Example of Method of Manufacturing Semiconductor Device)

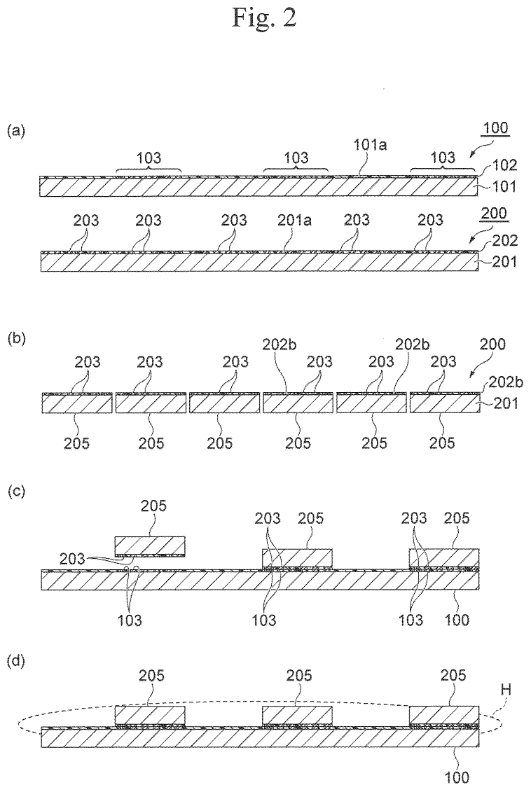

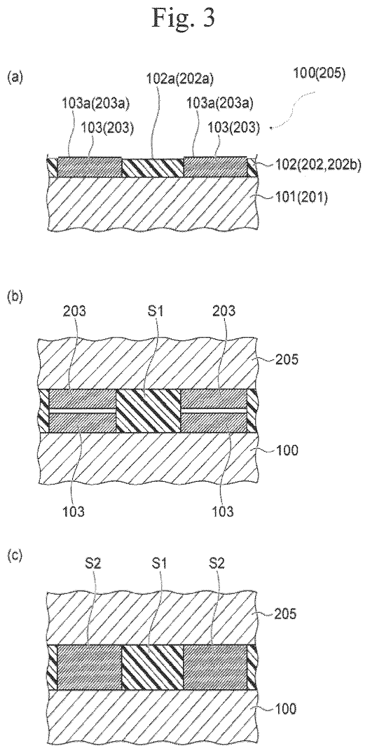

Next, one example of a method of manufacturing the semiconductor device 1 will be described with reference to FIG. 2 to FIG. 4. FIG. 2 is a diagram illustrating a method of manufacturing the semiconductor device illustrated in FIG. 1 in sequence. FIG. 3 is a diagram illustrating a bonding method (hybrid bonding) in the method of manufacturing a semiconductor device illustrated in FIG. 2 in more detail. FIG. 4 is a diagram illustrating a method of manufacturing the semiconductor device illustrated in FIG. 1, illustrating processes after the process illustrated in FIG. 2, in sequence.

The semiconductor device 1 can be produced, for example, through the following process (a) to process (n).
(a) A process of preparing a first semiconductor substrate 100 corresponding to the first semiconductor chip 10.
(b) A process of preparing a second semiconductor substrate 200 corresponding to the second semiconductor chip 20.
(c) A process of polishing one surface 101a of the first semiconductor substrate 100 using a polishing method such as CMP or polishing using a surface planer so that each surface 103a of terminal electrodes 103 is at the same position as or protrudes from a surface 102a of an insulating film 102 (see (a) in FIG. 3).
(c) A process of polishing one surface 201a of the second semiconductor substrate 200 using a polishing method such as CMP or polishing using a surface planer so that each surface 203a of terminal electrodes 203 is at the same position as or protrudes from a surface 202a of an insulating film 202 (see (a) in FIG. 3).
(e) A process of individualizing the second semiconductor substrate 200 to obtain a plurality of semiconductor chips 205 as illustrated in (b) of FIG. 2.
(f) A process of aligning a terminal electrode 203 of each of a plurality of semiconductor chips 205 with a terminal electrode 103 of the first semiconductor substrate 100 as illustrated in (c) of FIG. 2.
(g) A process of bonding an insulating film 102 of the first semiconductor substrate 100 and insulating film 202b of the plurality of semiconductor chips 205 to each other (see (d) in FIG. 2 and (b) in FIG. 3). At this time, heat H, pressure, or both may be applied.
(h) A process of bonding the terminal electrode 103 of the first semiconductor substrate 100 to the terminal electrode 203 of each of the plurality of semiconductor chips 205 (see (c) in FIG. 3).
(i) A process of forming a plurality of pillars 300 (corresponding to the pillar 31) on the connecting surface of the first semiconductor substrate 100 and between the plurality of semiconductor chips 205 (see (a) in FIG. 4).
(j) A process of molding a resin 301 on the connecting surface of the first semiconductor substrate 100 in such a manner to cover the semiconductor chips 205 and the pillars 300, thereby obtaining a semi-finished product M1 (see (b) in FIG. 4).
(k) A process of grinding and thinning the resin 301 side of the semi-finished product M1 molded in the process (j), thereby obtaining a semi-finished product M2 (see (c) in FIG. 4).
(l) A process of forming a wiring layer 400 corresponding to the rewiring layer 40 on the thinned semi-finished product M2 in the process (k) (see (d) in FIG. 4).
(m) A process of cutting a semi-finished product M3 on which the wiring layer 400 is formed in the process (1) along a cutting line A in such a manner to obtain semiconductor devices 1 (see (d) in FIG. 4).
(n) A process of inverting a semiconductor device 1a individualized in the process (m) and placing the device on the substrate 50 and the circuit board 60 (see FIG. 1).

For example, in a method of manufacturing a semiconductor device, the process (1) corresponds to the above-described process (a) and process (c), the process (2) corresponds to the above-described process (b) and process (d), the process (3) corresponds to process (e), the process (4) corresponds to process (g), and the process (5) corresponds to the process (h). Further, a material for forming an insulating film may be a material for forming an insulating film used for the manufacture of at least one insulating film of the first organic insulating film or the second organic insulating film in a method of manufacturing a semiconductor device.

The process (a) is a process of preparing the first semiconductor substrate 100, which is a silicon substrate on which an integrated circuit composed of semiconductor elements, wiring connecting the elements, and the like, corresponding to the plurality of first semiconductor chips 10, is formed. In the process (a), as illustrated in (a) of FIG. 2, on one side 101a of the first substrate body 101 made of silicon or the like, the plurality of terminal electrodes 103 (first electrodes) made of copper, aluminum, or the like are provided at predetermined intervals, and an insulating film 102 (first insulating film) that is a cured product obtained by curing the material for forming an insulating film of the disclosure is provided. When the material for forming an insulating film is a photosensitive material such as a negative-type photosensitive material for forming an insulating film or a positive-type photosensitive material for forming an insulating film, the insulating film 102 may be provided on the one surface 101 a of the first substrate body 101 before the plurality of terminal electrodes 103 are provided, or the plurality of terminal electrodes 103 may be provided on the one surface 101 a of the first substrate body 101 before the insulating film 102 is provided. When the material for forming an insulating film is a non-photosensitive material, the plurality of terminal electrodes 103 may be provided on the one surface 101 a of the first substrate body 101 before the insulating film 102 is provided.

The process (b) is a process of preparing the second semiconductor substrate 200, which is a silicon substrate on which an integrated circuit including semiconductor elements and wiring connecting the elements, corresponding to the plurality of second semiconductor chips 20, is formed. In the process (b), as illustrated in (b) of FIG. 2, on one side 201a of a second substrate body 201 made of silicon or the like, the plurality of terminal electrodes 203 (a plurality of second electrodes) made of copper, aluminum, or the like are continuously provided at predetermined intervals, and an insulating film 202 (second insulating film) that is a cured product obtained by curing the material for forming an insulating film of the disclosure is provided. When the material for forming an insulating film is a photosensitive material such as a negative-type photosensitive material for forming an insulating film or a positive-type photosensitive material for forming an insulating film, the insulating film 202 may be provided on the one surface 201 a of the first substrate body 201 before the plurality of terminal electrodes 103 are provided, or the plurality of terminal electrodes 203 may be provided on the one surface 201 a of the first substrate body 201 before the insulating film 202 is provided. When the material for forming an insulating film is a non-photosensitive material, the plurality of terminal electrodes 203 may be provided on the one surface 201 a of the first substrate body 101 before the insulating film 202 is provided.

The insulating films 102 and 202 used in processes (a) and (b) are not limited to being both cured products obtained by curing the material for forming an insulating film of the disclosure, and at least one of the insulating films 102 and 202 may be a cured product obtained by curing the material for forming an insulating film of the disclosure.

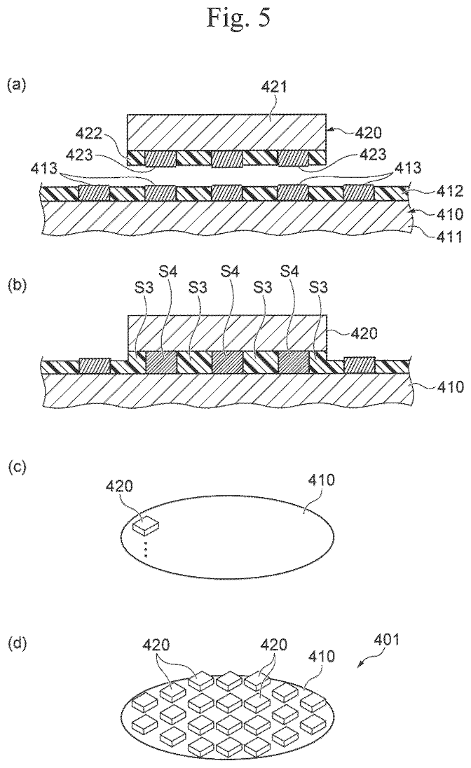

Although FIG. 1 illustrates an example of C2C bonding, the present invention may also be applied to chip-to-wafer (C2 W) bonding, as illustrated in FIG. 5. In C2 W, a semiconductor wafer 410 (first semiconductor substrate) is prepared, having a substrate body 411 (first substrate body), an insulating film 412 (first insulating film) provided on one surface of the substrate body 411, and a plurality of terminal electrodes 413 (first electrodes). Furthermore, a semiconductor substrate (second semiconductor substrate) before being broken into a plurality of semiconductor chips 420, is prepared, which has a substrate body 421 (second substrate body), an insulating film 422 (second insulating film) provided on one surface of the substrate body 421, and a plurality of terminal electrodes 423 (second electrodes). Then, one side of the semiconductor wafer 410 and one side of the second semiconductor substrate before being broken into the semiconductor chips 420 are polished by a polishing method such as CMP or polishing using a surface planer, as in processes (c) and (d) above. Thereafter, the second semiconductor substrate is broken into pieces similar to that in process (e) to obtain a plurality of semiconductor chips 420.

Next, as illustrated in (a) of FIG. 5, the terminal electrodes 423 of the semiconductor chip 420 are aligned with the terminal electrodes 413 of the semiconductor wafer 410 (process (f)). The insulating film 412 of the semiconductor wafer 410 and the insulating film 422 of the semiconductor chip 420 are then bonded together (process (g)), and the terminal electrodes 413 of the semiconductor wafer 410 and the terminal electrodes 423 of the semiconductor chip 420 are bonded together (process (h)), resulting in the semi-finished product illustrated in (b) of FIG. 5. This forms an insulating bonded portion S3 where the insulating film 412 and the insulating film 422 are bonded, and the semiconductor chip 420 is mechanically firmly attached to the semiconductor wafer 410 with high precision. Furthermore, the terminal electrodes 413 and the corresponding terminal electrodes 423 are bonded together to form an electrode bonded portion S4, where the terminal electrodes 413 and 423 are firmly bonded mechanically and electrically.

In process (h), as illustrated in (d) of FIG. 2, after the bonding in process (g) is completed, heat H, pressure, or both are applied to bond the terminal electrodes 103 of the first semiconductor substrate 100 to the terminal electrodes 203 of the multiple a plurality of semiconductor chips 205 using hybrid bonding (see (c) of FIG. 3). When the terminal electrodes 103 and 203 are made of copper, the annealing temperature in process (g) is preferably 150° C. or higher and 400° C. or lower, and more preferably 200° C. or higher and 300° C. or lower. In particular, using the material for forming an insulating film of the disclosure makes it possible to set the annealing temperature lower. This bonding process forms an electrode bonded portion S2 where the terminal electrode 103 and the corresponding terminal electrode 203 are bonded together, resulting in a strong mechanical and electrical bond between the terminal electrodes 103 and 203. The electrode bonding in process (h) may be performed after the attachment in process (g) or may be performed simultaneously with the attachment in process (g).

Then, as illustrated in (c) and (d) of FIG. 5, the plurality of semiconductor chips 420 are bonded to the semiconductor wafer 410 in a similar manner to obtain a semiconductor device 401. Note that the plurality of semiconductor chips 420 may be bonded individually to the semiconductor wafer 410 by hybrid bonding or may be bonded collectively to the semiconductor wafer 410 by hybrid bonding.

In this method of manufacturing a semiconductor device 401, as in the method of manufacturing a semiconductor device 1 described above, at least one of the insulating film 412 of the semiconductor wafer 410 or the insulating film 422 of the semiconductor chip 420 is an insulating film that is a cured product formed by curing the material for forming an insulating film of the disclosure. This makes it possible to reduce the difference in linear expansion coefficient between an insulating film and a terminal electrode such as a copper electrode, and when bonding the terminal electrodes together, it is possible to suppress poor bonding between the terminal electrodes due to the difference in linear expansion coefficient between the insulating film and the terminal electrode.

### Modified Example

In the semiconductor device and the method of manufacturing a semiconductor device of the disclosure, a configuration in which the first electrode and the second electrode are bonded has been described, but the present invention is not limited to this configuration.

For example, in the semiconductor device of the disclosure, the first electrode and the second electrode may be through-hole electrodes that penetrate the first semiconductor substrate and the second semiconductor substrate.

For example, the method of manufacturing a semiconductor device of the disclosure may be a method in which the material for forming an insulating film of the disclosure is used to produce at least one of the first organic insulating film or the second organic insulating film, and the semiconductor device is manufactured through the following processes (1)′ to (5)′.
Process (1)′ A first semiconductor substrate including a first substrate body and the first organic insulating film and a first electrode provided on one side of the first substrate body is prepared.
Process (2)′ A second semiconductor substrate including a second substrate body and the second organic insulating film and a second electrode provided on one side of the second substrate body is prepared.
Process (3)′ The second semiconductor substrate is broken into pieces to obtain a plurality of semiconductor chips each having the second organic insulating film.
Process (4)′ The first organic insulating film of the first semiconductor substrate and the second organic insulating film of the semiconductor chip are attached to each other.
Process (5)′ Through holes are formed in portions of the bonded first and second semiconductor substrates, and through electrodes are provided in the through holes.

In (5)′ above, the methods of forming the through holes and the through electrodes are not particularly limited. For example, the through holes may be formed by etching, or the through electrodes may be formed by electrolytic plating, electroless plating, sputtering, or the like.

### EXAMPLES

Hereinafter, the disclosure will be described in more detail based on Examples and Comparative Examples. The disclosure is not limited to the following Examples.

### Synthesis Example 1 (Synthesis of A1)

62 g of 3,3′,4,4′-diphenyl ether tetracarboxylic dianhydride (ODPA) and 36 g of 2,2′-dimethylbiphenyl-4,4′-diamine (DMAP) were dissolved in 915 g of 3-methoxy-N, N-dimethylpropionamide. The resulting solution was stirred at 30° C. for 2 hours to obtain a polyamide acid. Then 78 g of trifluoroacetic anhydride and 109 g of 2-hydroxyethyl methacrylate (HEMA) were added at room temperature, and then and stirring at 45° C. for 10 hours. The reaction liquid was added dropwise to distilled water, and the precipitate was filtered off, collected, and dried under reduced pressure to obtain a polyimide precursor (hereinafter, referred to as polymer A1).

The weight average molecular weight of polymer A1 was determined using gel permeation chromatography (GPC) by standard polystyrene conversion. The weight average molecular weight of polymer A1 was 25,000. Specifically, a solution of 0.5 mg of polymer A1 dissolved in 1 mL of solvent [tetrahydrofuran (THF)/dimethylformamide (DMF)=1/1 (volume ratio)] was used, and the measurement was performed under the following conditions.

### (Measurement Conditions)

Measure apparatus: SHIMADZU CORPORATION SPD-M20A
Pump: SHIMADZU CORPORATION LC-20AD
Column oven: SHIMADZU CORPORATION: CTO-20A
Measurement conditions: column Gelpack GL-S300MDT-5×2
Eluent: THF/DMF=1/1 (volume ratio)
   LiBr (0.03 mol/L), H₃PO₄ (0.06 mol/L)
   Flow velocity: 1.0 mL/min, detector: UV270 nm, column temperature: 40° C.
   Standard polystyrene: TSKgel standard Polystyrene Type F-1, F-4, F-20, F-80, A-2500 manufactured by Tosoh Corporation were used to create a calibration curve.

### Synthesis Example 2 (Synthesis of A2)

62 g of 3,3′,4,4′-diphenyl ether tetracarboxylic dianhydride (ODPA) and 23 g of 4,4′-diaminodiphenyl ether (ODA) and 5 g of m-phenylenediamine (MPD) were dissolved in 915 g of 3-methoxy-N, N-dimethylpropionamide. The resulting solution was stirred at 30° C. for 2 hours to obtain a polyamide acid. Then 78 g of trifluoroacetic anhydride and 109 g of 2-hydroxyethyl methacrylate (HEMA) were added at room temperature, and then and stirring at 45° C. for 10 hours. The reaction liquid was added dropwise to distilled water, and the precipitate was filtered off, collected, and dried under reduced pressure to obtain a polyimide precursor A2 (hereinafter, referred to as polymer A2).

The weight average molecular weight of polymer A2 was determined in the same manner as in polymer A1. The weight average molecular weight of polymer A2 was 22,000.

### Examples 1 to 7, Comparative Examples 1 to 3

### (Preparation of Material for Forming Insulating Film)

Materials for forming an insulating film of Examples 1 to 7 and Comparative Examples 1 to 3 were prepared as follows with the ingredients and blended amounts shown in Table 1. The unit for the blended amounts of components in Table 1 is parts by mass. “−” in Table 1 means that the relevant component has not been blended. In each of Examples and Comparative Examples, the mixture of each component was kneaded overnight at room temperature in a general solvent-resistant container, and then pressure filtered using a 3 μm pore filter. The obtained materials for forming an insulating film were subjected to the following evaluations.

For C1 and C2, each of which corresponds to (C) the component, fillers dispersed in a solvent were used. The values in parentheses for (C) the component in Table 1 indicate the solid content of the filler with respect to 100 parts by mass of (A) the component.

Each of the components in Table 1 are as follows:
(A) Component
A1: Polymer A1 synthesized in Synthesis Example 1 described above
A2: Polymer A2 synthesized in Synthesis Example 2 described above
(B) Component
B1: γ-butyrolactone
B2: 3-methoxy-N,N-dimethylpropionamide
B3: Cyclohexanone
(C) Component
C1: Silica particles (volume average particle size: 22 nm, surface treatment: hydrophobic
treatment, dispersion solvent: cyclohexanone, non-volatile content: 30% by mass)
C2: Silica particles (volume average particle size: 50 nm, surface treatment: methacrylic treatment,
dispersion solvent: cyclohexanone, non-volatile content: 40% by mass)
C3: Silica particles (volume average particle size: 12 nm, powder without surface treatment, no
dispersion solvent)
(D) Component
D1: Tetraethylene glycol dimethacrylate (TEGDMA)
D2: Ethoxylated pentaerythritol tetraacrylate (ATM-4E, total number of ethoxy groups: 4)
(E) Component
E: 1-phenyl-1,2-propanedione-2-(O-ethoxycarbonyl) oxime
(F) Component
F: 4,4′-bis(diethylamino)benzophenone
(G) Component
G: 50% ethanol solution of 3-ureidopropyltriethoxysilane
   [i-Line Transmittance]

The obtained material for forming an insulating film was spin-coated onto a glass substrate using a spin coater, dried at 100° C. for 2 minutes, and then dried at 110° C. for 2 minutes to form a resin film. The transmittance of the formed resin film at 365 nm i-line was measured using a U-3900H spectrophotometer (Hitachi High-Tech Science Corporation). The results are shown in Table 1.

### [Resolution Evaluation]

The obtained material for forming an insulating film was spin-coated onto a silicon wafer using an Act8 coating system (Tokyo Electron Limited), dried at 100° C. for 2 minutes, and then dried at 110° C. for 2 minutes to form a photosensitive resin film with a dry thickness of 10 to 12 μm.

The obtained photosensitive resin film was immersed in cyclopentanone and the development time was set to twice the time required for complete dissolution.

A photosensitive resin film was then formed in the same manner as above, and exposed to light at a dose of 400 mJ/cm² using an i-line stepper NES2WA06 (Nikon Corporation).

After post-exposure baking, the resin film was puddle-developed in cyclopentanone using Act8 for the development time specified above, followed by rinsing with propylene glycol monomethyl ether acetate (PGMEA) to obtain a patterned resin film.

The obtained patterned cured product was observed using an optical microscope, and the resolution was determined as the smallest diameter at which an opening, with exposed substrate surface, which has 55% or more with respect to the area of the via mask dimension, was formed. A resolution of 30 μm or less was rated A, a resolution of more than 30 μm and less than 50 μm was rated B, and a resolution of more than 50 μm was rated C. An Evaluation of A or B indicates that the resolution result is good.

The results are shown in Table 1.

### [Measurement of Thermal Expansion Coefficient]

The obtained material for forming an insulating film was used to form a cured film as follows, and then the thermal expansion coefficient was measured. The material for forming an insulating film was spin-coated onto a Si substrate and dried by heating on a hot plate at 100° C. for 120 seconds, followed by heating at 110° C. for 120 seconds, to form a resin film with a thickness of approximately 10 μm after curing.

The resulting resin film was cured in a vertical u-TF diffusion furnace under a nitrogen atmosphere at 200° C. for 2 hours to obtain a cured product with a film thickness of 10 μm. The obtained cured product was then immersed in a 4.9% by weight aqueous solution of hydrofluoric acid and peeled from the Si substrate. The cured product was then cut into a 10 mm wide pattern using a razor blade to obtain a patterned cured product with 10 mm wide

Using a TMA testing device (TMA8310, manufactured by Rigaku Corporation), the linear thermal expansion coefficient of the patterned cured product in the surface direction from 50° C. to 100° C. was measured under the conditions of an initial sample length of 10 mm, a load of 10 g, and a heating rate of 5° C./min. The results obtained are shown in Table 1 as linear expansion coefficients (ppm/K).

TABLE 1

| | Example | | | | | | | Comparative Example | | |
|---|---|---|---|---|---|---|---|---|---|---|
| | 1 | 2 | 3 | 4 | 5 | 6 | 7 | 1 | 2 | 3 |
| A1 | 100 | 100 | 100 | 100 | — | 100 | 100 | 100 | — | 100 |
| A2 | — | — | — | — | 100 | — | — | — | 100 | — |
| B1 | 150 | 130 | 150 | 130 | 150 | — | 75 | 150 | 150 | 150 |
| B2 | — | — | — | — | — | 150 | — | — | — | — |
| B3 | — | — | — | — | — | — | 75 | — | — | — |
| C1 | 65 (20) | 100 (30) | — | — | — | — | — | — | — | — |
| C2 | — | — | 50 (20) | 75 (30) | 50 (20) | 50 (20) | 50 (20) | — | — | — |
| C3 | — | — | — | — | — | — | — | — | — | 20 |
| D1 | 20 | 20 | 20 | 20 | 20 | 20 | 20 | 20 | 20 | 20 |
| D2 | 15 | 15 | 15 | 15 | 15 | 15 | 15 | 15 | 15 | 15 |
| E | 3 | 3 | 3 | 3 | 3 | 3 | 3 | 3 | 3 | 3 |
| F | 0.5 | 0.5 | 0.5 | 0.5 | 0.5 | 0.5 | 0.5 | 0.5 | 0.5 | 0.5 |
| G | 3 | 3 | 3 | 3 | 3 | 3 | 3 | 3 | 3 | 3 |
| i-line (365 nm) | 12 | 12 | 15 | 15 | 20 | 8 | 12 | 15 | 20 | 2 |
| transmittance | | | | | | | | | | |
| Resolution | A | A | A | A | A | B | A | A | A | C |
| Linear expansion | 45 | 40 | 50 | 45 | 50 | 50 | 50 | 65 | 65 | 50 |
| coefficient | | | | | | | | | | |
| (ppm/K) | | | | | | | | | | |

As shown in Table 1, Examples 1 to 7 had good resolution evaluation and were able to reduce the linear expansion coefficient. On the other hand, Comparative Examples 1 and 2 had higher linear expansion coefficients than Examples 1 to 7. Comparative Example 3 had a poor resolution evaluation compared to Examples 1 to 7.

The disclosure of Japanese Patent Application No. 2023-068850 is incorporated herein by reference in its entirety. All references, patent applications, and technical standards described herein are incorporated by reference herein to the same extent that individual references, patent applications, and technical standards are specifically and individually noted as being incorporated by reference.

Reference Signs List
1, 1a, 401 . . . Semiconductor device, 10 . . .
First semiconductor chip, 20 . . . Second
semiconductor chip, 30 . . . Pillar portion, 40 . . .
Rewiring layer, 50 . . . Substrate, 60 . . . Circuit board,
61 . . . Terminal electrode, 100 . . . First semiconductor
substrate, 101 . . . First substrate body, 101a . . .
One side, 102 . . . Insulating film (first insulating film),
103 . . . Terminal electrode (first electrode),
103a . . . Surface, 200 . . . Second semiconductor
substrate, 201 . . . Second substrate body, 201a . . .
One side, 202 . . . Insulating film (second
insulating film), 203 . . . Terminal electrode (second
electrode), 203a . . . Surface, 205 . . . Semiconductor
chip, 300 . . . Pillar, 301 . . . Resin, 410 . . .
Semiconductor wafer (first semiconductor substrate),
411 . . . Substrate body (first substrate body),
412 . . . Insulating film (first insulating film),
413 . . . Terminal electrode (first electrode), 420 . . .
Semiconductor chip (second semiconductor substrate),
421 . . . Substrate body (second substrate
body), 422 . . . Insulating film (second insulating
film), 423 . . . Terminal electrode (second
electrode), A . . . Cutting line, H . . . Heat, M1 to
M3 . . . Semi-finished product, S1 . . . Insulated
bonding portion, S2 . . . Electrode bonding portion,
S3 . . . Insulated bonding portion, S4 . . . Electrode
bonding portion.

1. A material for forming an insulating film comprising:
(A) a polyimide precursor
(B) a solvent and
(C) a filler,
wherein an i-line transmittance of an insulating film formed by the material for forming an insulating film is from 5% to 40% and the material has photosensitivity.

2. The material for forming an insulating film according to claim 1, wherein the polyimide precursor includes a compound having a structural unit represented by the following general formula (1); 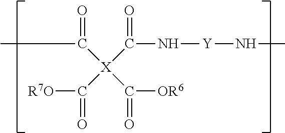
in general formula (1), X represents a tetravalent organic group, Y represents a divalent organic group, each of R⁶ and R⁷ independently represents a hydrogen atom or a monovalent organic group, and at least one of R⁶ and R⁷ has a polymerizable unsaturated bond.

3. The material for forming an insulating film according to claim 1, further comprising (D) a polymerizable monomer and (E) a photoinitiator.

4. The material for forming an insulating film according to claim 1, wherein an average particle size of the filler is from 10 nm to 100 nm.

5. The material for forming an insulating film according to claim 1, wherein the filler is surface-treated.

6. The material for forming an insulating film according to claim 1, wherein the solvent includes a non-amide solvent.

7. The material for forming an insulating film according to claim 6, wherein the non-amide solvent includes a cyclic ester compound.

8. The material for forming an insulating film according to claim 1, wherein the material is used to form an insulating film for a hybrid bonding.

9. A method of manufacturing a semiconductor device comprising: producing an organic insulating film of at least one of a first organic insulating film or a second organic insulating film by using the material for forming an insulating film according to claim 8, and bonding the first organic insulating film and the second organic insulating film.

10. A method of manufacturing a semiconductor device comprising:
a process of forming a via by applying a material for forming an insulating film on a first substrate body and then removing a portion of the material for forming an insulating film applied on the first substrate body,
a process of preparing a first semiconductor substrate including a first organic insulating film and a first electrode provided on one side of the first substrate body, by curing the material for forming an insulating film in which the via is formed on the first substrate body to form the first organic insulating film and filing an electrode material into the via to form the first electrode,
a process of forming a via by applying a material for forming an insulating film on a second substrate body and then removing a portion of the material for forming an insulating film applied on the second substrate body,
a process of preparing a second semiconductor substrate including a second organic insulating film and a second electrode provided on one side of the second substrate body, by curing the material for forming an insulating film in which the via is formed on the second substrate body to form the second organic insulating film and filing an electrode material into the via to form the second electrode,
a process of obtaining a plurality of semiconductor chips by individuating the second semiconductor substrate, and
a process of attaching the first organic insulating film of the first semiconductor substrate to the second organic insulating film of the second insulating film each other and bonding the first electrode of the first semiconductor substrate and the second electrode of the semiconductor chip, wherein
at least one of the material for forming an insulating film applied on the first substrate body or the material for forming an insulating film applied on the second substrate body is the material for forming an insulating film according to claim 8.

11. A semiconductor device comprising:
a first semiconductor substrate including a first substrate body, and a first organic insulating film and a first electrode provided on one side of the first substrate body; and
a semiconductor chip including a semiconductor chip substrate body, and a second organic insulating film and a second electrode provided on one side of the semiconductor chip substrate body, wherein
the first organic insulating film of the first semiconductor substrate and the second organic insulating film of the semiconductor chip are bonded, and the first electrode of the first semiconductor substrate and the second electrode of the semiconductor chip are bonded, and
at least one of the first organic insulating film or the second organic insulating film is an insulating film obtained by curing a photosensitive material for forming an insulating film containing (A) a polyimide precursor, and (C) a filler, and an i-line transmittance of the insulating film is from 5% to 40%.
